(19) United States
(12) Patent Application Publication
(10) Pub. No.: US 2025/0212384 A1
(43) Pub. Date: Jun. 26, 2025

(54) SEMICONDUCTOR DEVICES

(71) Applicant: Samsung Electronics Co., Ltd., Suwon-si (KR)

(72) Inventor: Moonju Hong, Suwon-si (KR)

(21) Appl. No.: 18/782,108

(22) Filed: Jul. 24, 2024

(30) Foreign Application Priority Data
Dec. 20, 2023 (KR) 10-2023-0187258

(51) Int. Cl. H10B 12/00

(52) U.S. Cl. CPC H10B 12/30; H10B 12/05

(57) ABSTRACT

A semiconductor device may include a bit line that extends in a first direction, a bit-line dielectric layer on a sidewall of the bit line, a channel layer in contact with the bit line, a word line that extends in a second direction that intersects the first direction, a gate capping layer in contact with a first sidewall of the word line, a gate dielectric layer in contact with the channel layer and a second sidewall of the word line, and a first dielectric structure that extends in the first direction. The first dielectric structure may include a dielectric material that is different from a dielectric material of the gate capping layer. The word line, the gate dielectric layer, and the gate capping layer may be in contact with an inner sidewall of the first dielectric structure.

### CROSS-REFERENCE TO RELATED APPLICATION

This U.S. nonprovisional application claims priority under 35 U.S.C. § 119 to Korean Patent Application No. 10-2023-0187258 filed on Dec. 20, 2023, in the Korean Intellectual Property Office, and the entire contents of the above-identified application are hereby incorporated by reference.

### BACKGROUND

The present disclosure relate to semiconductor devices, and more particularly, to semiconductor devices including dielectric structures.

A reduction in design rule of semiconductor devices may induce development of fabrication technology to increase integration, operating speeds, and/or manufacturing yield of semiconductor devices. Accordingly, transistors with vertical channels have been suggested to increase their integration, resistance, current driving capability, and so forth.

### SUMMARY

Some embodiments of the present inventive concepts provide a semiconductor device with improved electrical properties and increased integration.

According to some embodiments of the present inventive concepts, a semiconductor device may comprise: a bit line that extends in a first direction; a bit-line dielectric layer on a sidewall of the bit line; a channel layer in contact with the bit line; a word line that extends in a second direction that intersects the first direction; a gate capping layer in contact with a first sidewall of the word line; a gate dielectric layer in contact with the channel layer and a second sidewall of the word line, the second sidewall of the word line opposite to the first sidewall; and a first dielectric structure that extends in the first direction. The first dielectric structure may include a dielectric material that is different from a dielectric material of the gate capping layer. The word line, the gate dielectric layer, and the gate capping layer may be in contact with an inner sidewall of the first dielectric structure.

According to some embodiments of the present inventive concepts, a semiconductor device may comprise: a bit line that extends in a first direction; a bit-line dielectric layer on a sidewall of the bit line; a channel layer in contact with the bit line; a word line that extends in a second direction that intersects the first direction; a gate capping layer in contact with a first sidewall of the word line; a gate dielectric layer in contact with the channel layer and a second sidewall of the word line, the second sidewall of the word line being opposite to the first sidewall; and a dielectric structure in contact with a third sidewall of the word line. The gate dielectric layer and the dielectric structure may each include an oxide. The bit-line dielectric may include: a first top surface in contact with the gate dielectric layer; and a second top surface in contact with a bottom surface of the dielectric structure.

According to some embodiments of the present inventive concepts, a semiconductor device may comprise: a bit line that extends in a first direction; a bit-line dielectric layer on a sidewall of the bit line; a channel layer in contact with the bit line; a word line that extends in a second direction that intersects the first direction; a gate capping layer in contact with a first sidewall of the word line; a gate dielectric layer in contact with the channel layer and a second sidewall of the word line, the second sidewall of the word line being opposite to the first sidewall; a dielectric structure in contact with a third sidewall of the word line; a first dielectric pattern in contact with the gate capping layer; a second dielectric pattern spaced apart from the first dielectric pattern across the dielectric structure; an upper capping layer in contact with the gate capping layer, the first dielectric pattern, and the second dielectric pattern; an upper dielectric layer on the upper capping layer; a landing pad that extends at least into the upper dielectric layer and is in contact with the channel layer; and a data storage pattern connected to the landing pad. A bottom surface of the upper capping layer may be in contact with a top surface of the dielectric structure.

### BRIEF DESCRIPTION OF DRAWINGS

FIG. 1A illustrates a block diagram showing a semiconductor device according to some embodiments.

FIGS. 1B and 1C illustrate simplified perspective views showing a semiconductor device according to some embodiments.

FIG. 2 illustrates a plan view showing a semiconductor device according to some embodiments.

FIG. 3 illustrates a cross-sectional view taken along line A-A′ of FIG. 2.

FIG. 4A illustrates a cross-sectional view taken along line B-B′ of FIG. 2.

FIG. 4B illustrates a cross-sectional view taken along line C-C′ of FIG. 2.

FIG. 4C illustrates a cross-sectional view taken along line D-D′ of FIG. 2.

FIGS. 5A, 5B, and 5C illustrate cross-sectional views showing a semiconductor device according to some embodiments.

FIGS. 6A, 6B, and 6C illustrate cross-sectional views showing a semiconductor device according to some embodiments.

FIGS. 7, 8A, 8B, 8C, 9A, 9B, 9C, 10A, 10B, 10C, 11A, 11B, 11C, 12, 13A, 13B, and 13C illustrate diagrams showing a method of fabricating a semiconductor device according to some embodiments.

FIG. 14 illustrates a plan view showing a semiconductor device according to some embodiments.

FIG. 15 illustrates a cross-sectional view taken along line A-A′ of FIG. 14.

FIG. 16A illustrates a cross-sectional view taken along line B-B′ of FIG. 14.

FIG. 16B illustrates a cross-sectional view taken along line C-C′ of FIG. 14.

FIG. 16C illustrates a cross-sectional view taken along line D-D′ of FIG. 14.

### DETAILED DESCRIPTION OF EMBODIMENTS

It will be hereinafter discussed a semiconductor package and a method of fabricating the same according to some embodiments of the present inventive concept in conjunction with the accompanying drawings.

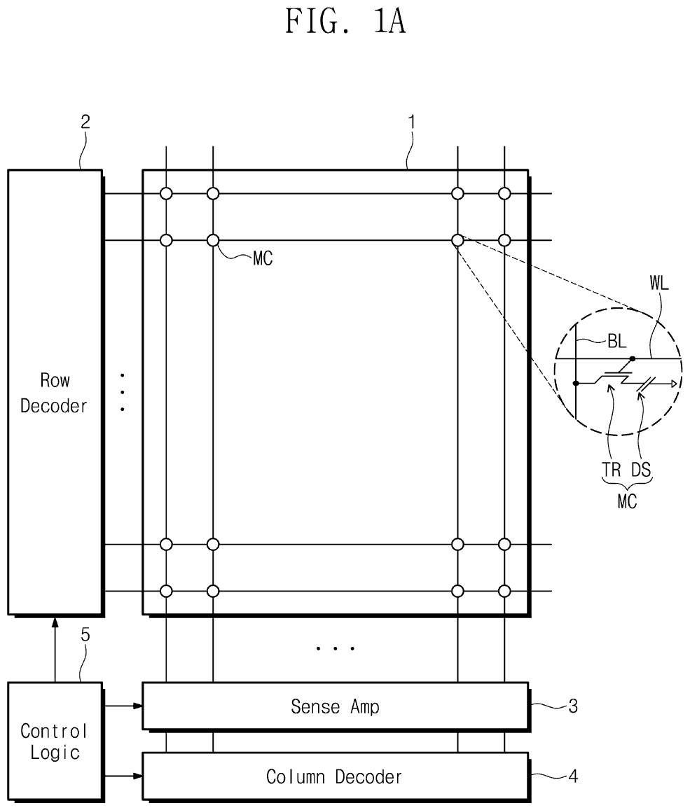

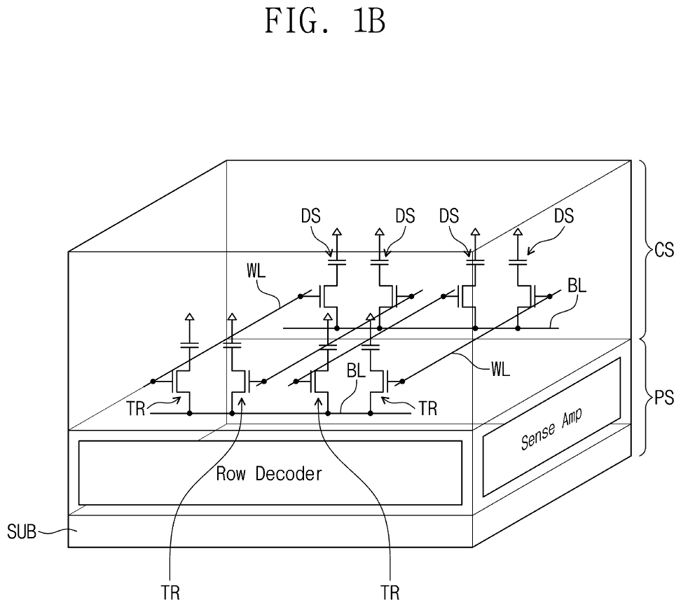

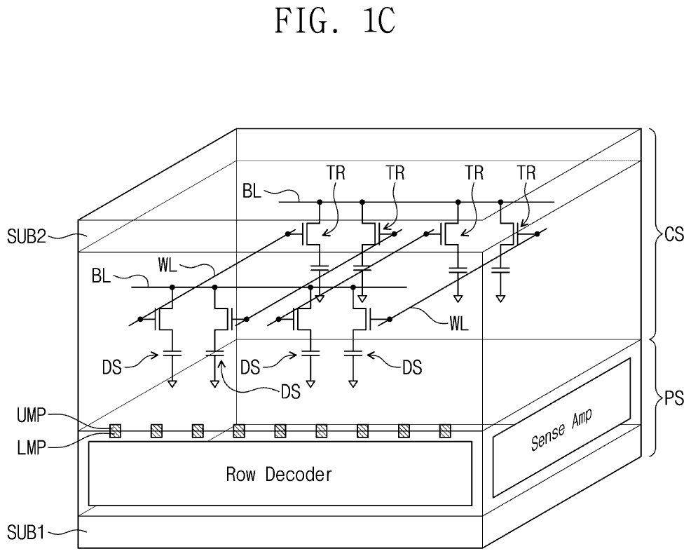

FIG. 1A illustrates a block diagram showing a semiconductor device according to some embodiments.

Referring to FIG. 1A, a semiconductor device may include a memory cell array 1, a row decoder 2, a sense amplifier 3, a column decoder 4, and a control logic 5.

The memory cell array 1 may include a plurality of memory cells MC that are arranged two-dimensionally or three-dimensionally. Each of the memory cells MC may be connected between and to a word line WL and a bit line BL that intersect each other.

Each of the memory cells MC may include a selection element TR and a data storage element DS. The selection element TR and the data storage element DS may be electrically connected to each other. The selection element TR may be connected to both of the word line WL and the bit line BL. For example, the selection element TR may be provided at an intersection between the word line WL and the bit line BL.

The selection element TR may include a field effect transistor. The data storage element DS may include a capacitor, a magnetic tunnel junction pattern, or a variable resistor. For example, a gate terminal of a transistor as the selection element TR may be connected to the word line WL, and a first source/drain terminal of the transistor may be connected to the bit line BL and a second source/drain terminal of the transistor may be connected to the data storage element DS.

The row decoder 2 may decode an address that is input from an external source (not shown) and may select one of the word lines WL of the memory cell array 1. The address decoded in the row decoder 2 may be provided to a row driver (not shown), and in response to a control operation of control circuits, the row driver may provide a first certain voltage to a selected word line WL and a second certain voltage to each of non-selected word lines WL.

The column decoder 4 may provide a data delivery pathway between the sense amplifier 3 and an external device (e.g., a memory controller). The column decoder 4 may decode an address that is input from an external source and may select one of the bit lines BL. In response to the address decoded by the column decoder 4, the sense amplifier 3 may detect and amplify a voltage difference between the selected bit line BL and a reference bit line, and may then output the amplified voltage difference.

The control logic 5 may generate control signals that control operations to write data to the memory cell array 1 and/or to read data from the memory cell array 1.

FIGS. 1B and 1C illustrate simplified perspective views showing a semiconductor device according to some embodiments.

Referring to FIGS. 1B and 1C, a semiconductor device may include a peripheral circuit structure PS and a cell array structure CS connected to the peripheral circuit structure PS.

The peripheral circuit structure PS may include core/peripheral circuits formed on a substrate SUB. The core/peripheral circuits may include the row and column decoders 2 and 4, the sense amplifier 3, and the control logic 5 that are discussed with reference to FIG. 1A.

The cell array structure CS may include a memory cell array (see 1 of FIG. 1A) including memory cells (see MC of FIG. 1A) arranged two-dimensionally or three-dimensionally. Each of the memory cells (see MC of FIG. 1A) may include, as discussed above, a selection element TR and a data storage element DS.

In some embodiments, a vertical channel transistor (VCT) may be included as the selection element TR of each memory cell (see MC of FIG. 1A). The vertical channel transistor may include a channel whose lengthwise direction is perpendicular to a top surface of the substrate SUB. The data storage element DS of each memory cell (see MC of FIG. 1A) may include a capacitor.

In the example of FIG. 1B, the peripheral circuit structure PS may be provided on the substrate SUB, and the cell array structure CS may be provided on the peripheral circuit structure PS.

In the example of FIG. 1C, the peripheral circuit structure PS may be provided on a first substrate SUB1, and the cell array structure CS may be provided on a second substrate SUB2. The first substrate SUB1 and the second substrate SUB2 may face each other.

The peripheral circuit structure PS may be provided on its uppermost portion with first metal pads LMP. The first metal pads LMP may be electrically connected to the core/peripheral circuits (see 2, 3, 4, and 5 of FIG. 1A).

The cell array structure CS may be provided on its lowermost portion with second metal pads UMP. The second metal pads UMP may be electrically connected to the memory cell array (see 1 of FIG. 1A). The second metal pads UMP may be in direct contact with or bonded to the first metal pads LMP of the peripheral circuit structure PS.

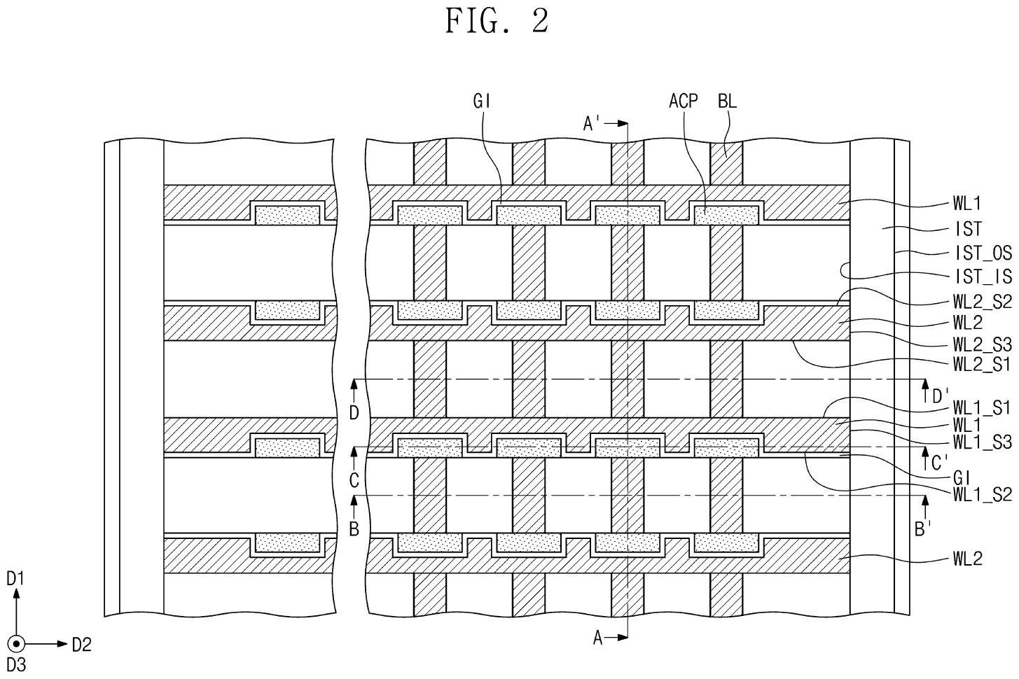

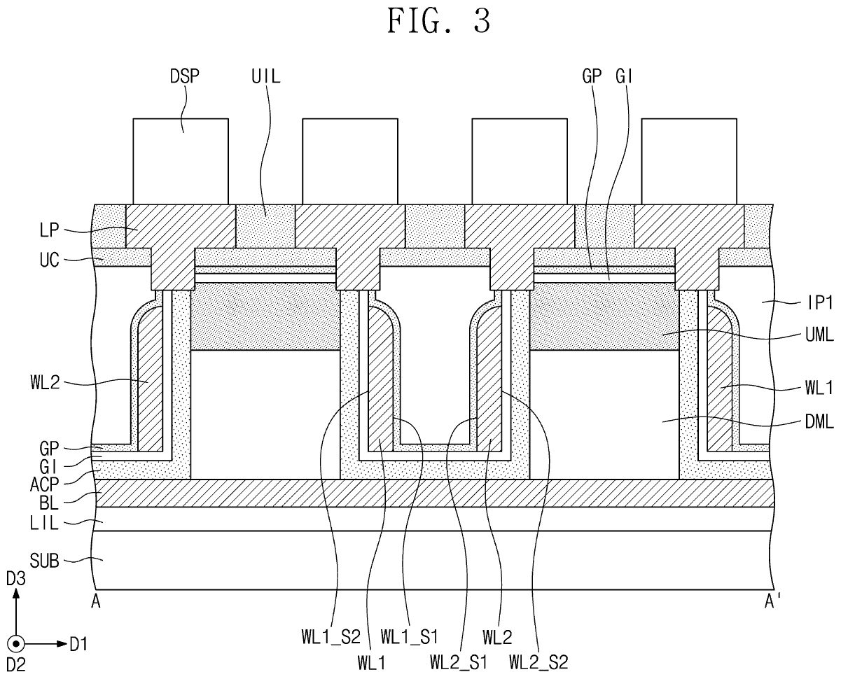

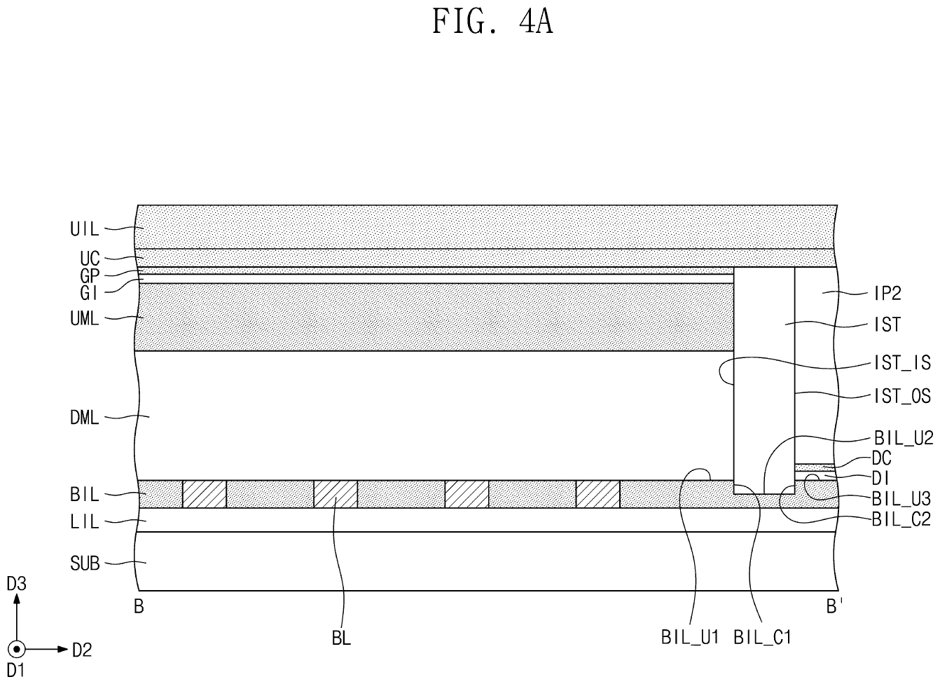

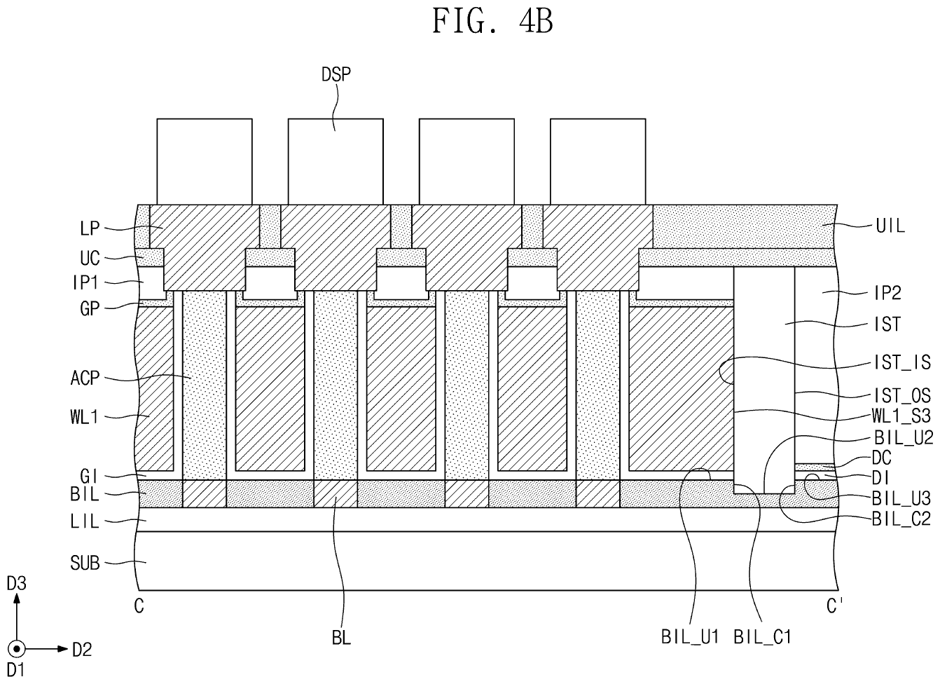

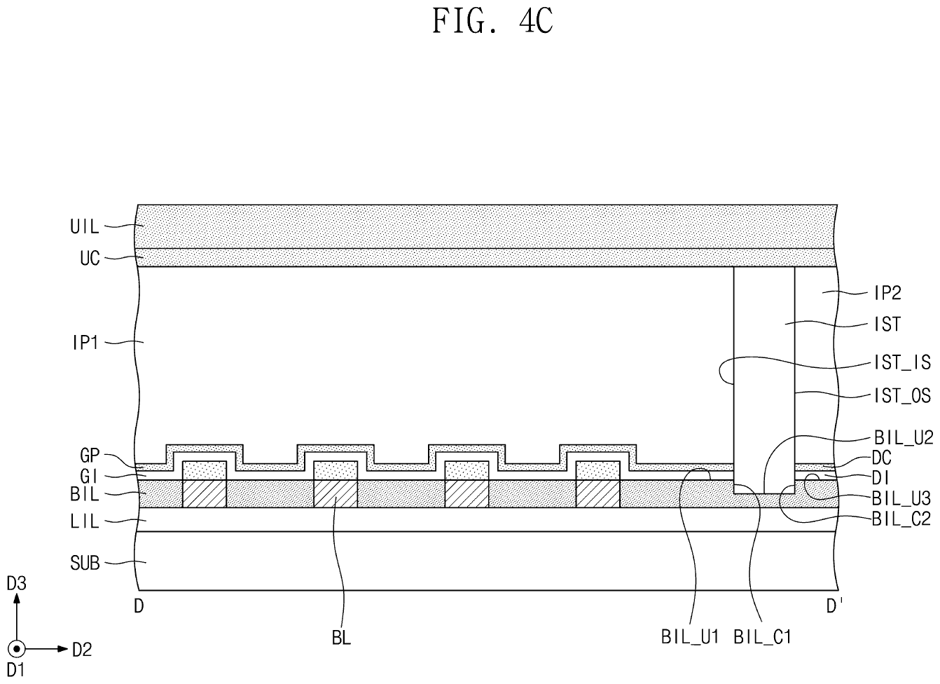

FIG. 2 illustrates a plan view showing a semiconductor device according to some embodiments. FIG. 3 illustrates a cross-sectional view taken along line A-A′ of FIG. 2. FIG. 4A illustrates a cross-sectional view taken along line B-B′ of FIG. 2. FIG. 4B illustrates a cross-sectional view taken along line C-C′ of FIG. 2. FIG. 4C illustrates a cross-sectional view taken along line D-D′ of FIG. 2.

Referring to FIGS. 2 to 4C, a lower dielectric layer LIL may be provided on a substrate SUB. The substrate SUB may have a plate shape elongated along a plane defined by a first direction D1 and a second direction D2. The first direction D1 and the second direction D2 may intersect each other. For example, the first direction D1 and the second direction D2 may be horizontal directions that are orthogonal to each other. The lower dielectric layer LIL may include a dielectric material. For example, the lower dielectric layer LIL may include oxide.

In some embodiments, the peripheral circuit structure PS discussed with reference to FIG. 1B may be provided between the substrate SUB and the lower dielectric layer LIL. In some embodiments, an integrated circuit, such as a logic device, may be provided between the substrate SUB and the lower dielectric layer LIL.

A bit-line dielectric layer BIL may be provided on the lower dielectric layer LIL. The bit-line dielectric layer BIL may include a dielectric material. A plurality of bit lines BL may be provided in the bit-line dielectric layer BIL. The bit-line dielectric layer BIL may be in (e.g., may fill) a space between sidewalls of the bit lines BL. The bit lines BL may extend in the first direction D1. The bit lines BL may be arranged along the second direction D2. The bit line BL may be spaced apart from each other in the second direction D2.

The bit line BL may include a conductive material. The bit line BL may include, for example, at least one material selected from doped polysilicon, metal (e.g., Al, Cu, Ti, Ta, Ru, W, Mo, Pt, Ni, or Co), conductive metal nitride (e.g., TiN, TaN, WN, NbN, TiAlN, TiSiN, TaSiN, or RuTiN), conductive metal silicide, and conductive metal oxide (e.g., PtO, RuO₂, IrO₂, SRO (SrRuO₃), BSRO((Ba,Sr)RuO₃), CRO(CaRuO₃), or LSCo), but the present inventive concepts are not limited thereto. The bit line BL may include a single layer or multiple layers of the materials mentioned above. In some embodiments, the bit line BL may include a two-dimensional semiconductor material, such as graphene, carbon nano-tube, or any combination thereof.

The bit lines BL may be provided with channel layers ACP thereon. A plurality of channel layers ACP may be in contact with one bit line BL. The channel layers ACP provided on one bit line BL may be arranged along the second direction D2.

The channel layer ACP may include a semiconductor material. The channel layer ACP may include an oxide semiconductor, which oxide semiconductor may include at least one selected from InGaZnO, InGaSiO, InSnZnO, InZnO, ZnO, ZnSnO, ZnON, ZrZnSnO, SnO, HfInZnO, GaZnSnO, AlZnSnO, YbGaZnO, and InGaO, but the present inventive concepts are not limited thereto. For example, the channel layer ACP may include indium-gallium-zinc oxide (IGZO). The channel layer ACP may include a single or multiple layer of the oxide semiconductor. The channel layer ACP may include an amorphous, crystalline, or polycrystalline oxide semiconductor. In some embodiments, the channel layer ACP may have a bandgap energy greater than that of silicon. For example, the channel layer ACP may have a bandgap energy of about 1.5 eV to about 5.6 eV. For example, the channel layer ACP may exhibit optimum channel performance when its bandgap energy ranges from about 2.0 eV to about 4.0 eV. For example, the channel layer ACP may be polycrystalline or amorphous, but the present inventive concepts are not limited thereto. In some embodiments, the channel layer ACP may include a two-dimensional semiconductor material, such as graphene, carbon nano-tube, or any combination thereof.

First word lines WL1 and second word lines WL2 may be provided. The first word line WL1 and the second word line WL2 may be provided on a gate dielectric layer GI which will be discussed below. The first word line WL1 and the second word line WL2 may be in contact with a gate dielectric layer GI which will be discussed below. The first word line WL1 and the second word line WL2 may be spaced apart from each other in the first direction D1. The first word line WL1 and the second word line WL2 may extend in the second direction D2.

The first word line WL1 and the second word line WL2 may include a conductive material. The first word line WL1 and the second word line WL2 may include, for example, at least one material selected from doped polysilicon, metal (e.g., Al, Cu, Ti, Ta, Ru, W, Mo, Pt, Ni, or Co), conductive metal nitride (e.g., TiN, TaN, WN, NbN, TiAlN, TiSiN, TaSiN, or RuTiN), conductive metal silicide, and conductive metal oxide, but the present inventive concepts are not limited thereto. The first word line WL1 and the second word line WL2 may include a single layer or multiple layers of the materials mentioned above. In some embodiments, the first word line WL1 and the second word line WL2 may include a two-dimensional semiconductor material, such as graphene, carbon nano-tube, or any combination thereof.

The first word line WL1 may have a first sidewall WL1_S1, a second sidewall WL1_S2, and a third sidewall WL1_S3. The second word line WL2 may have a first sidewall WL2_S1, a second sidewall WL2_S2, and a third sidewall WL2_S3. The first sidewall WL1_S1 of the first word line WL1 may face the first sidewall WL2_S1 of the second word line WL2. Adjacent sidewalls of the first word line WL1 and the second word line WL2 may be the first sidewalls WL1_S1 and WL2_S1 of the first word line WL1 and the second word line WL2. The second sidewall WL1_S2 of the first word line WL1 may be opposite to the first sidewall WL1_S1 of the first word line WL1. The second sidewall WL2_S2 of the second word line WL2 may be opposite to the first sidewall WL2_S1 of the second word line WL2. The first sidewall WL1_S1 and the second sidewall WL1_S2 of the first word line WL1 may extend in the second direction D2, and likewise the first sidewall WL2_S1 and the second sidewall WL2_S2 of the second word line WL2 may extend in the second direction D2. The third sidewall WL1_S3 of the first word line WL1 may connect the first sidewall WL1_S1 and the second sidewall WL1_S2 of the first word line WL1 to each other. The third sidewall WL2_S3 of the second word line WL2 may connect the first sidewall WL2_S1 and the second sidewall WL2_S2 of the second word line WL2 to each other. The third sidewall WL1_S3 of the first word line WL1 and the third sidewall WL2_S3 of the second word line WL2 may be in contact with a dielectric structure IST which will be discussed below.

A gate dielectric layer GI may be provided on the channel layer ACP. The gate dielectric layer GI may be in contact with the channel layer ACP, the second sidewall WL1_S2 of the first word line WL1, the second sidewall WL2_S2 of the second word line WL2, and a gate capping layer GP which will be discussed in greater detail below. The gate dielectric layer GI may extend in the second direction D2. The gate dielectric layer GI may include a dielectric material. For example, the gate dielectric layer GI may include an oxide.

A gate capping layer GP may be provided. The gate capping layer GP may be provided on the first and second word lines WL1 and WL2 and on the gate dielectric layer GI. The gate capping layer GP may be in contact with the first sidewall WL1_S1 of the first word line WL1 and the first sidewall WL2_S1 of the second word line WL2. The gate capping layer GP may include a dielectric material. For example, the gate capping layer GP may include nitride.

Lower molding layers DML may be provided on the bit line BL. The lower molding layer DML may be provided between the channel layers ACP that are adjacent to each other in the first direction D1. The lower molding layer DML may be provided on the bit lines BL that are arranged in the second direction D2. The lower molding layer DML may be in contact with the channel layers ACP that are adjacent to each other and with the bit lines BL that are arranged in the second direction D2. The lower molding layer DML may connect the channel layer ACP to a dielectric structure IST which will be discussed in greater detail below. The lower molding layer DML may include a dielectric material.

Upper molding layers UML may be provided. The upper molding layer UML may be provided on the lower molding layer DML. The upper molding layer UML may be provided between the channel layers ACP that are adjacent to each other. The upper molding layer UML may be in contact with a top surface of the lower molding layer DML and the channel layers ACP that are adjacent to each other. The upper molding layer UML may include a dielectric material.

A dielectric structure IST may be provided. The dielectric structure IST may extend in the first direction D1. The dielectric structure IST may be spaced apart in the second direction D2 from the bit lines BL. The dielectric structure IST may be in contact with the bit-line dielectric layer BIL, the first word line WL1, the second word line WL2, the gate dielectric layer GI, and the gate capping layer GP. The dielectric structure IST may include a dielectric material.

A first dielectric pattern IP1 may be provided on the gate capping layer GP. The first dielectric pattern IP1 may cover the gate capping layer GP. The first dielectric pattern IP1 may be in contact with the gate capping layer GP and the dielectric structure IST.

A second dielectric pattern IP2 may be provided. The second dielectric pattern IP2 may be spaced apart from the first dielectric pattern IP1 across the dielectric structure IST. The second dielectric pattern IP2 may be in contact with the dielectric structure IST.

The first dielectric pattern IP1 and the second dielectric pattern IP2 may include a dielectric material. For example, the first dielectric pattern IP1 and the second dielectric pattern IP2 may include an oxide.

As seen best in FIGS. 4A-4C, a dummy dielectric layer DI and a dummy capping layer DC may be provided between the bit-line dielectric layer BIL and the second dielectric pattern IP2. The dummy dielectric layer DI may be provided on the bit-line dielectric layer BIL. The dummy capping layer DC may be on the dummy dielectric layer DI. The dummy dielectric layer DI may be in contact with the bit-line dielectric layer BIL, the dummy capping layer DC, and the dielectric structure IST. The dummy capping layer DC may be in contact with the second dielectric pattern IP2, the dummy dielectric layer DI, and the dielectric structure IST. The dummy dielectric layer DI may be spaced apart from the gate dielectric layer GI across the dielectric structure IST. The dummy capping layer DC may be spaced apart from the gate capping layer GP across the dielectric structure IST. The dummy dielectric layer DI and the dummy capping layer DC may include a dielectric material. For example, the dummy dielectric layer DI may include oxide, and the dummy capping layer DC may include nitride.

An upper capping layer UC may be provided. The upper capping layer UC may be on the gate capping layer GP, the first dielectric pattern IP1, the second dielectric pattern IP2, and the dielectric structure IST. The upper capping layer UC may be in contact with a top surface of the gate capping layer GP, a top surface of the first dielectric pattern IP1, a top surface of the second dielectric pattern IP2, and a top surface of the dielectric structure IST. The upper capping layer UC may include a dielectric material. The upper capping layer UC may include nitride.

Landing pads LP may be provided on the channel layers ACP. The landing pad LP may vertically overlap the channel layer ACP. The landing pads LP may be spaced apart from each other in the first direction D1 and the second direction D2, and may be arranged in a matrix pattern, a zigzag pattern, a honeycomb pattern, or any other suitable pattern. When viewed in plan, the landing pads LP may each have a circular shape, an oval shape, a rectangular shape, a square shape, a rhombic shape, a hexagonal shape, or any other suitable shape.

The landing pads LP may include a conductive material. The landing pads LP may be formed of, for example, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or any combination thereof, but the present inventive concepts are not limited thereto.

An upper dielectric layer UIL may be provided between the landing pads LP. The upper dielectric layer UIL may be provided on the upper capping layer UC. The upper dielectric layer UIL may be in contact with a top surface of the upper capping layer UC. The upper dielectric layer UIL may separate the landing pads LP from each other. The upper dielectric layer UIL may include a dielectric material. For example, the upper dielectric layer UIL may include nitride.

Data storage patterns DSP may be correspondingly provided on the landing pads LP. The data storage pattern DSP may be electrically connected through the landing pad LP to the channel layer ACP.

In some embodiments, the data storage pattern DSP may be a capacitor that includes a bottom electrode, a top electrode, and a capacitor dielectric layer between the bottom and top electrodes. In this case, the bottom electrode may be in contact with the landing pad LP, and when viewed in plan, may have a circular shape, an oval shape, a rectangular shape, a square shape, a rhombic shape, a hexagonal shape, or any other suitable shape. The shape of the bottom electrode of the capacitor or data storage pattern DSP may correspond to the shape of the landing pad LP.

In some embodiments, the data storage pattern DSP may be a variable resistance pattern whose two resistance states are switched due to an electrical pulse. For example, the data storage pattern DSP may include a phase-change material whose crystalline state is changed based on an amount of current, perovskite compounds, transition metal oxide, magnetic materials, ferromagnetic materials, or antiferromagnetic materials.

The dielectric structure IST may have an inner sidewall IST_IS, an outer sidewall IST_OS, a top surface, and a bottom surface. The inner sidewall IST_IS of the dielectric structure IST may be in contact with the bit-line dielectric layer BIL, the lower molding layer DML, the upper molding layer UML, the gate dielectric layer GI, the gate capping layer GP, the third sidewall WL1_S3 of the first word line WL1, the third sidewall WL2_S3 of the second word line WL2, and the first dielectric pattern IP1. The outer sidewall IST_OS of the dielectric structure IST may be in contact with the bit-line dielectric layer BIL, the dummy dielectric layer DI, the dummy capping layer DC, and the second dielectric pattern IP2. The top surface of the dielectric structure IST may be in contact with a bottom surface of the upper capping layer UC. The top surface of the dielectric structure IST may be coplanar with that of the gate capping layer GP, that of the first dielectric pattern IP1, and that of the second dielectric pattern IP2. The bottom surface of the dielectric structure IST may be in contact with the bit-line dielectric layer BIL. The dielectric structure IST may extend into the bit-line dielectric layer BIL.

The bit-line dielectric layer BIL may have a first top surface BIL_U1, a second top surface BIL_U2, a third top surface BIL_U3, a first connection surface BIL_C1, and a second connection surface BIL_C2. The first top surface BIL_U1 of the bit-line dielectric layer BIL may be in contact with the lower molding layer DML and the gate dielectric layer GI. The second top surface BIL_U2 of the bit-line dielectric layer BIL may be in contact with the bottom surface of the dielectric structure IST. The third top surface BIL_U3 of the bit-line dielectric layer BIL may be in contact with the dummy dielectric layer DI. The second top surface BIL_U2 of the bit-line dielectric layer BIL may be located at a level lower than that of the first top surface BIL_U1 of the bit-line dielectric layer BIL and that of the third top surface BIL_U3 of the bit-line dielectric layer BIL. The first connection surface BIL_C1 of the bit-line dielectric layer BIL may connect the first top surface BIL_U1 and the second top surface BIL_U2 of the bit-line dielectric layer BIL to each other. The first connection surface BIL_C1 of the bit-line dielectric layer BIL may be in contact with the inner sidewall IST_IS of the dielectric structure IST. The second connection surface BIL_C2 of the bit-line dielectric layer BIL may connect the second top surface BIL_U2 and the third top surface BIL_U3 of the bit-line dielectric layer BIL to each other. The second connection surface BIL_C2 of the bit-line dielectric layer BIL may be in contact with the outer sidewall IST_OS of the dielectric structure IST.

The dielectric structure IST, the gate capping layer GP, the first dielectric pattern IP1, and the second dielectric pattern IP2 may have their top surfaces that are coplanar with each other.

The dielectric structure IST may include a dielectric material different from that of the bit-line dielectric layer BIL and that of the upper molding layer UML. The dielectric structure IST may include a dielectric material the same as that of the lower molding layer DML. For example, the dielectric structure IST and the lower molding layer DML may include oxide, and the bit-line dielectric layer BIL and the upper molding layer UML may include nitride.

A semiconductor device according to some embodiments may include the dielectric structure IST by which oxygen molecules are supplied through the lower molding layer DML to the channel layer ACP when an annealing process is performed. Thus, vacancies of the channel layer ACP may be filled with oxygen molecules to reduce a resistance of the channel layer ACP and to improve electrical properties of the semiconductor device.

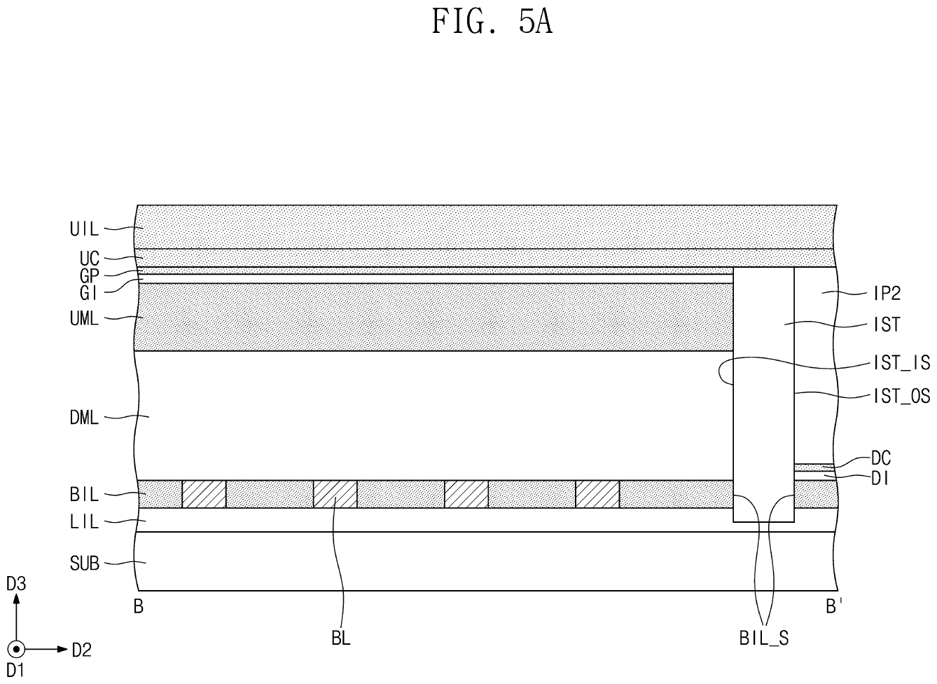

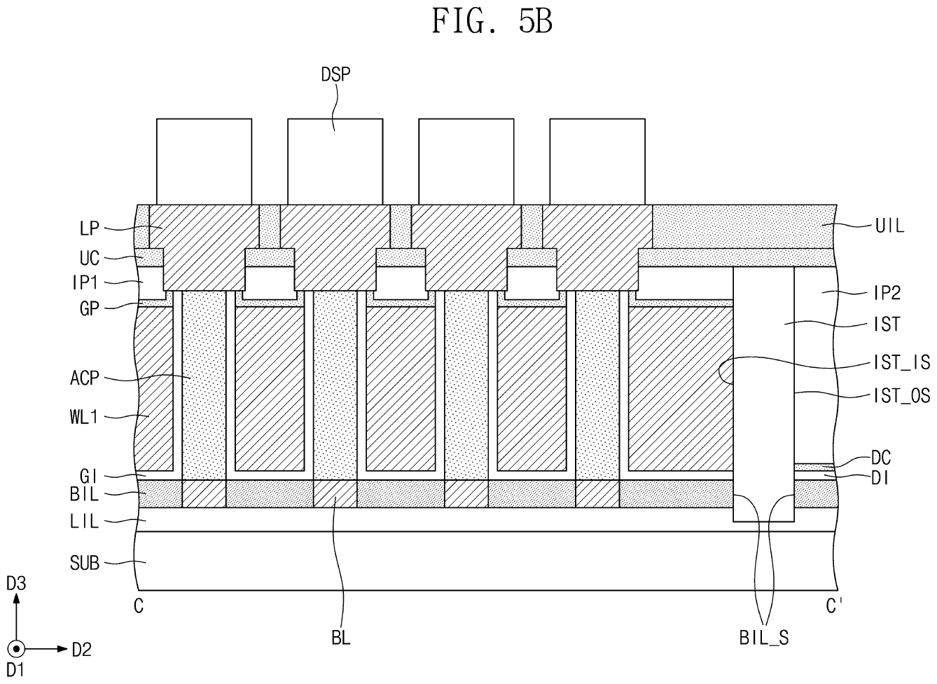

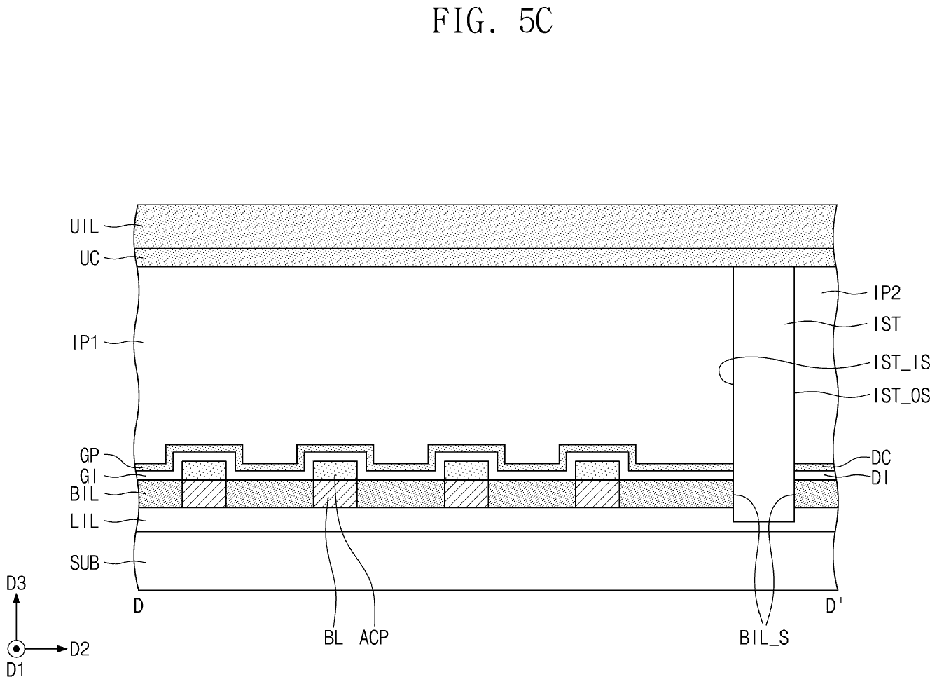

FIGS. 5A, 5B, and 5C illustrate cross-sectional views showing a semiconductor device according to some embodiments. FIG. 5A shows a cross-sectional view that corresponds to FIG. 4A. FIG. 5B shows a cross-sectional view that corresponds to FIG. 4B. FIG. 5C shows a cross-sectional view that corresponds to FIG. 4C. A semiconductor device of FIGS. 5A, 5B, and 5C may be similar to that of FIGS. 2 to 4C, except for the following description.

Referring to FIGS. 5A, 5B, and 5C, the dielectric structure IST may extend through the bit-line dielectric layer BIL. The bit-line dielectric layer BIL may have a sidewall BIL_S. The sidewall BIL_S of the bit-line dielectric layer BIL may be in contact with the inner sidewall IST_IS and the outer sidewall IST_OS of the dielectric structure IST. The bottom surface of the dielectric structure IST may be in contact with the lower dielectric layer LIL. The bottom surface of the dielectric structure IST may be located at a level lower than that of a bottom surface of the bit-line dielectric layer BIL and that of a bottom surface of the bit line BL.

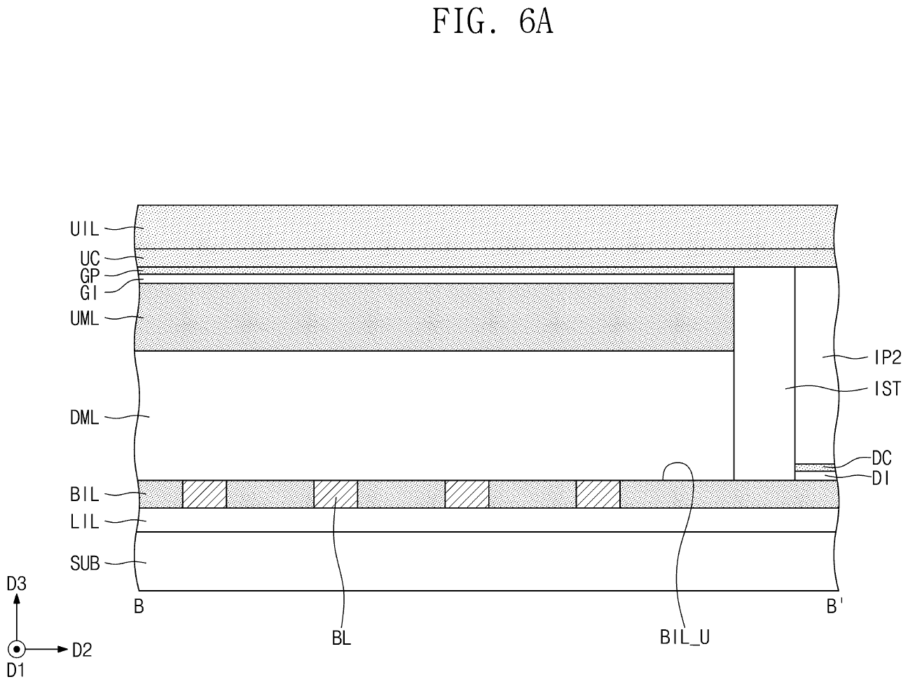

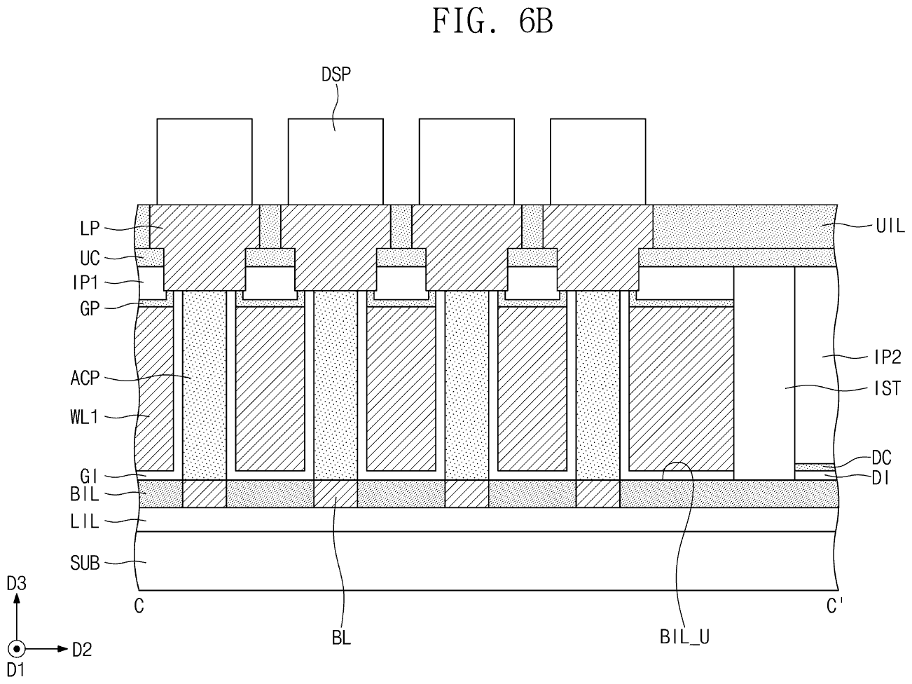

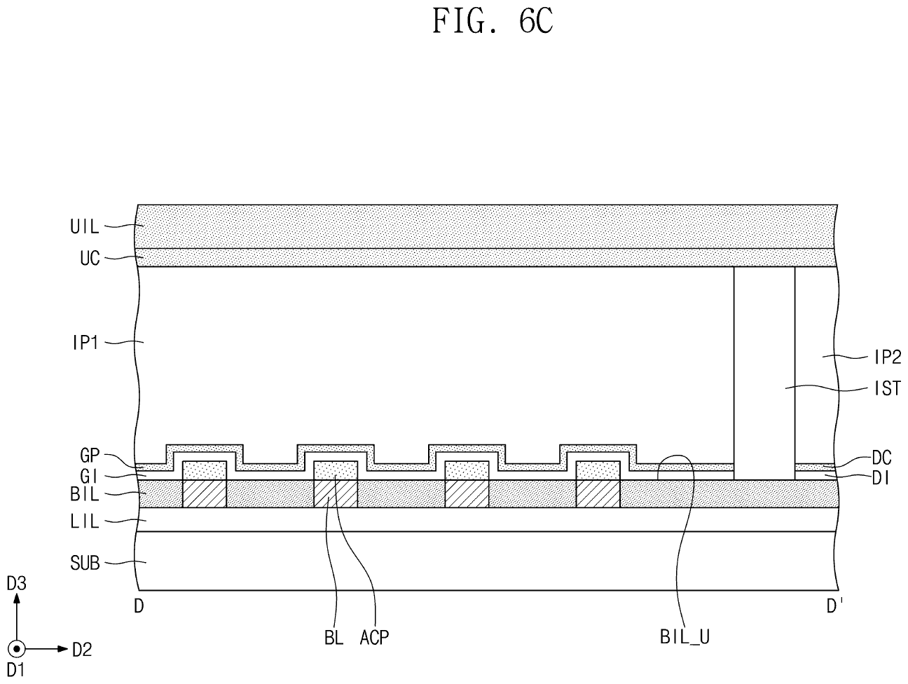

FIGS. 6A, 6B, and 6C illustrate cross-sectional views showing a semiconductor device according to some embodiments. FIG. 6A illustrates a cross-sectional view that corresponds to FIG. 4A. FIG. 6B shows a cross-sectional view that corresponds to FIG. 4B. FIG. 5C shows a cross-sectional view that corresponds to FIG. 4C. A semiconductor device of FIGS. 6A, 6B, and 6C may be similar to that of FIGS. 2 to 4C, except for the following description.

Referring to FIGS. 6A, 6B, and 6C, the bottom surface of the dielectric structure IST may be in contact with a top surface BIL_U of the bit-line dielectric layer BIL. The top surface BIL_U of the bit-line dielectric layer BIL may be coplanar with a top surface of the bit line BL. The bottom surface of the dielectric structure IST may be coplanar with that of the lower molding layer DML, that of the gate dielectric layer GI, and that of the dummy dielectric layer DI.

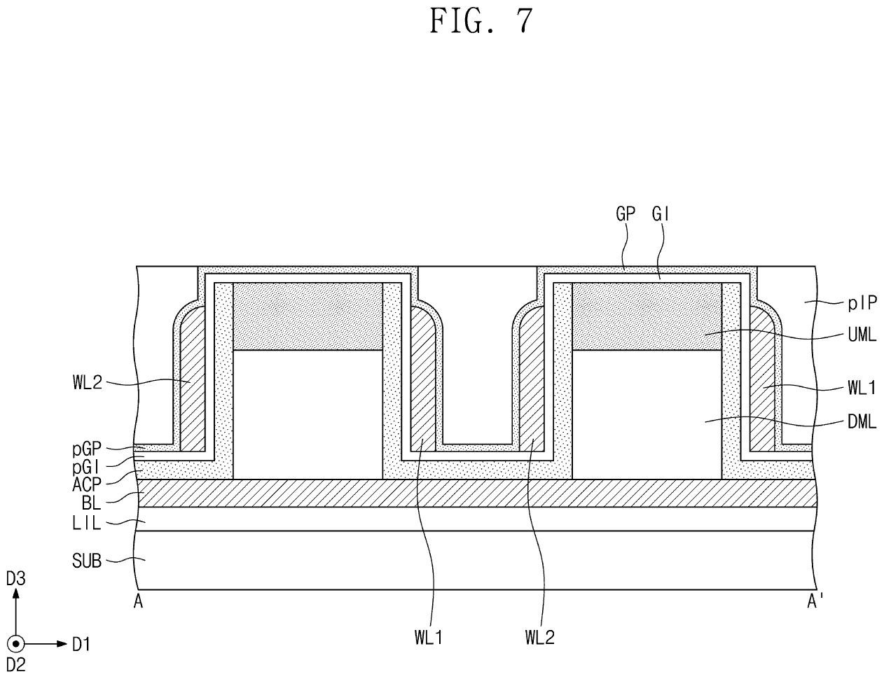

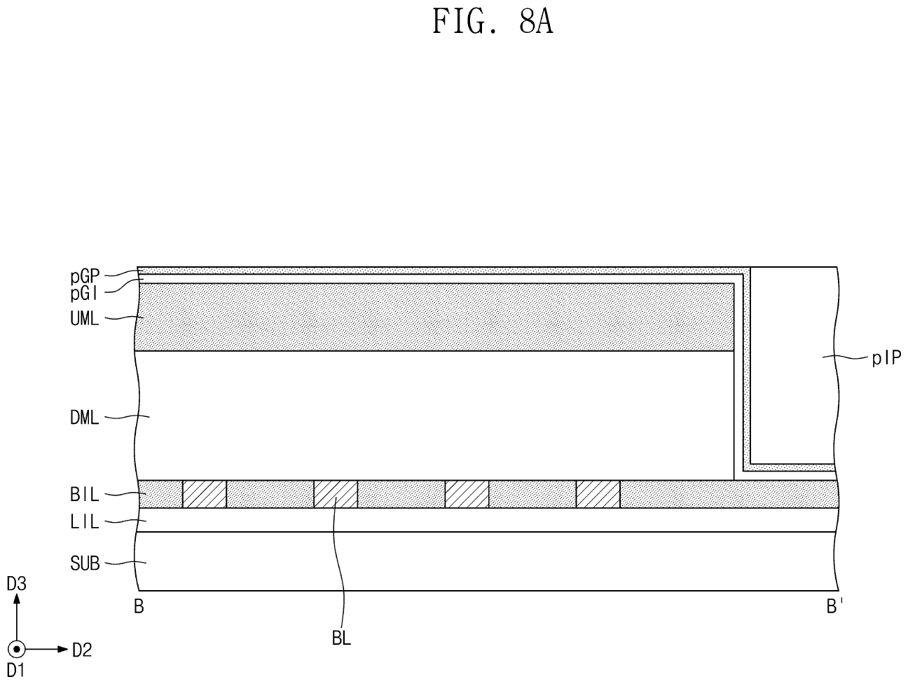

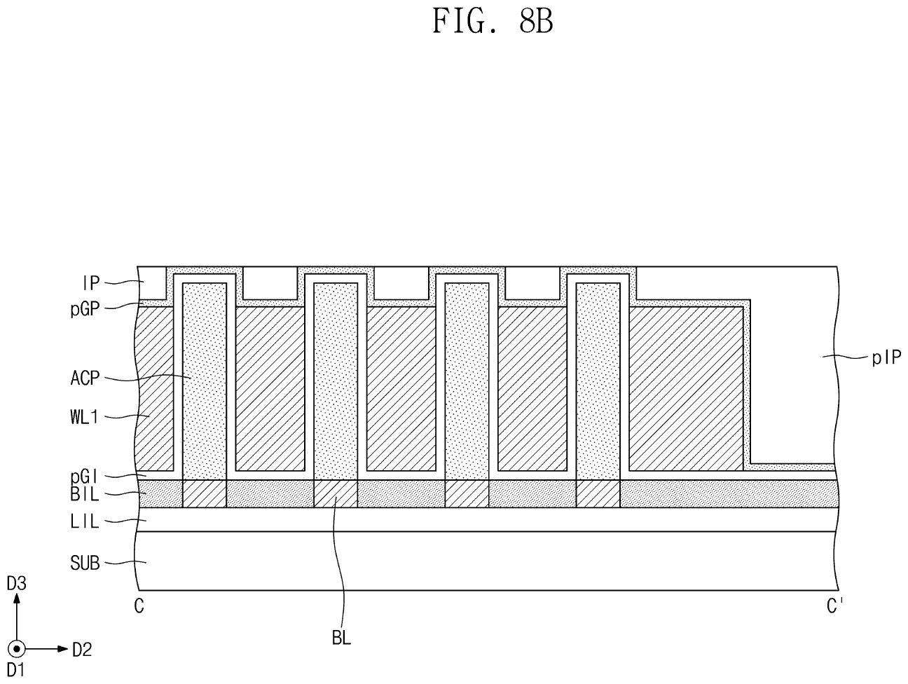

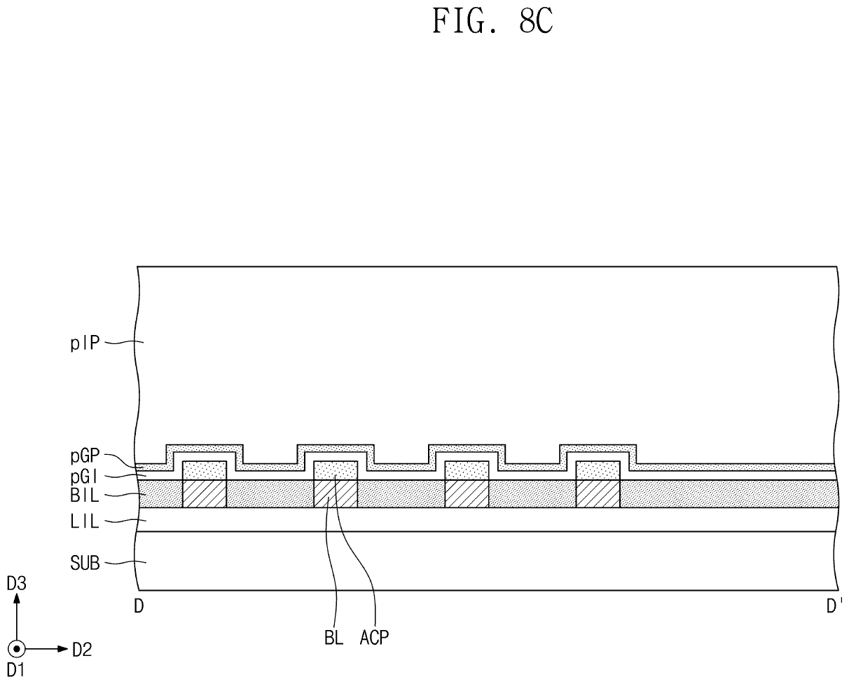

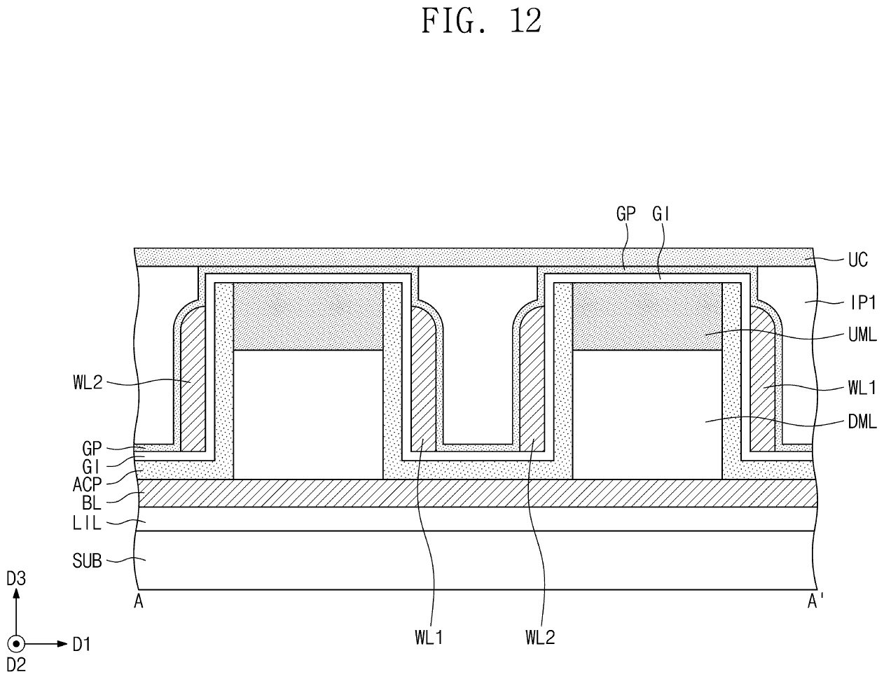

FIGS. 7, 8A, 8B, 8C, 9A, 9B, 9C, 10A, 10B, 10C, 11A, 11B, 11C, 12, 13A, 13B, and 13C illustrate diagrams showing a method of fabricating a semiconductor device according to some embodiments. FIGS. 7 and 12 may correspond to FIG. 3. FIGS. 8A, 9A, 10A, 11A, and 13A may correspond to FIG. 4A. FIGS. 8B, 9B, 10B, 11B, and 13B may correspond to FIG. 4B. FIGS. 8C, 9C, 10c, 11C, and 13C may correspond to FIG. 4C.

Referring to FIGS. 7, 8A, 8B, and 8C, a lower dielectric layer LIL may be formed on the substrate SUB. A bit-line dielectric layer BIL may be formed on the lower dielectric layer LIL. Bit lines BL may be formed in the bit-line dielectric layer BIL.

Lower molding layers DML and upper molding layers UML may be formed on the bit-line dielectric layer BIL. The upper molding layer UML may be formed on the lower molding layer DML. Channel layers ACP may be formed between the lower molding layers DML that are adjacent to each other in a first direction D1 and between the upper molding layers UML that are adjacent to each other in the first direction D1. A preliminary gate dielectric layer pGI may be formed on the lower molding layers DML, the upper molding layers UML, the channel layers ACP, and the bit-line dielectric layer BIL. The preliminary gate dielectric layer pGI may cover and conform to the lower molding layers DML, the upper molding layers UML, the channel layers ACP, and the bit-line dielectric layer BIL. First word lines WL1 and second word lines WL2 may be formed on the preliminary gate dielectric layer pGI. A preliminary gate capping layer pGP may be formed on the preliminary gate dielectric layer pGI, the first word lines WL1, and the second word lines WL2. The preliminary gate capping layer pGP may cover and conform to the preliminary gate dielectric layer pGI, the first word lines WL1, and the second word lines WL2.

The preliminary gate dielectric layer pGI and the preliminary gate capping layer pGP may include a dielectric material. For example, the preliminary gate dielectric layer pGI may include an oxide, and the preliminary gate capping layer pGP may include a nitride.

A preliminary dielectric pattern pIP may be formed on the preliminary gate capping layer pGP. The formation of the preliminary dielectric pattern pIP may include forming the preliminary dielectric pattern pIP that covers the preliminary gate capping layer pGP, and removing an upper portion of the preliminary dielectric pattern pIP to expose a top surface of the preliminary gate capping layer pGP.

In some embodiments, the upper portion of the preliminary dielectric pattern pIP may be removed by a chemical mechanical polishing (CMP) process. Therefore, the preliminary dielectric pattern pIP and the preliminary gate capping layer pGP may have their top surfaces that are coplanar with each other.

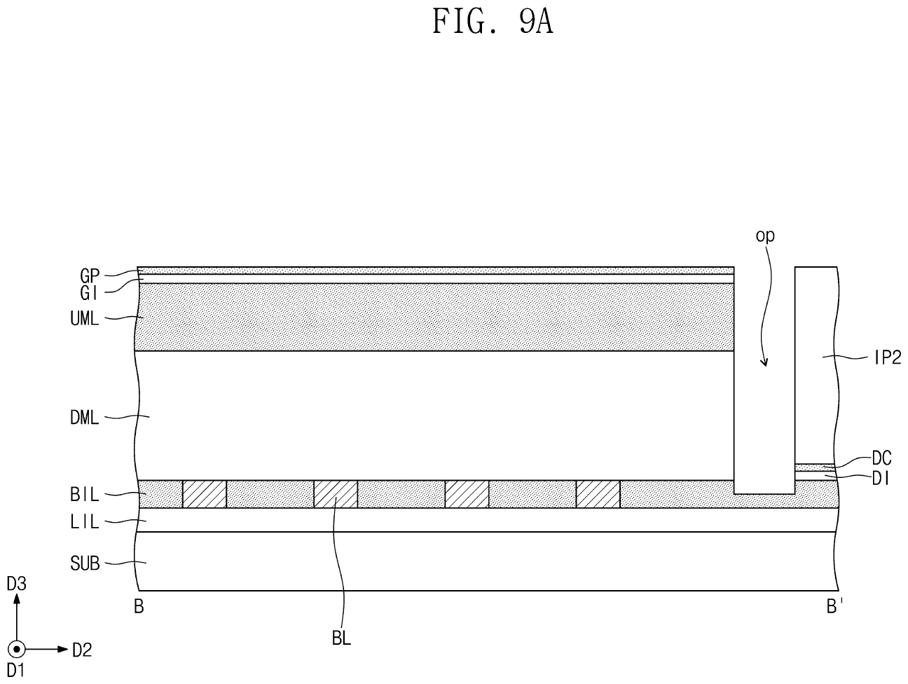

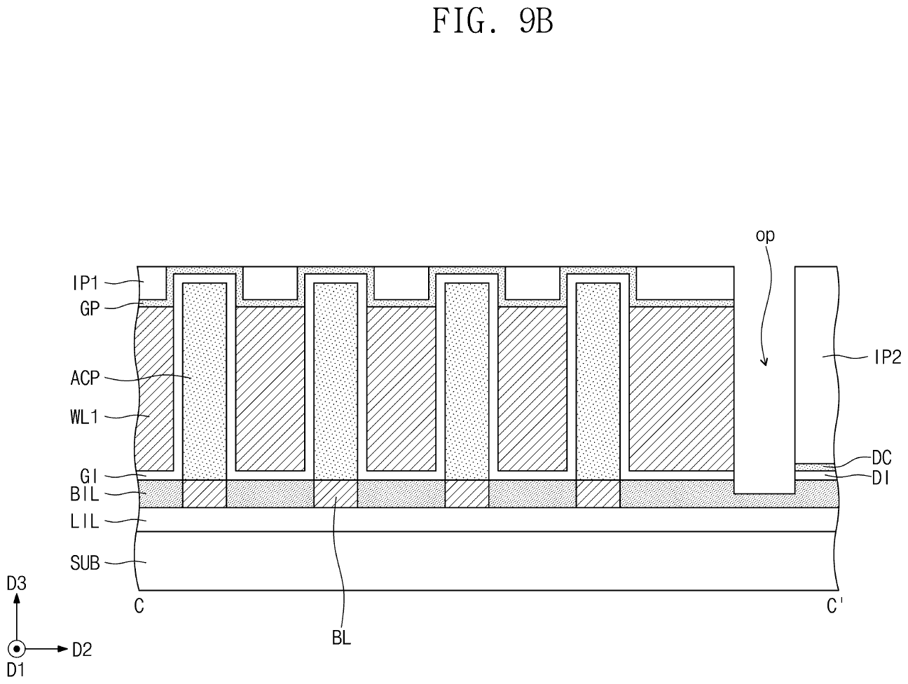

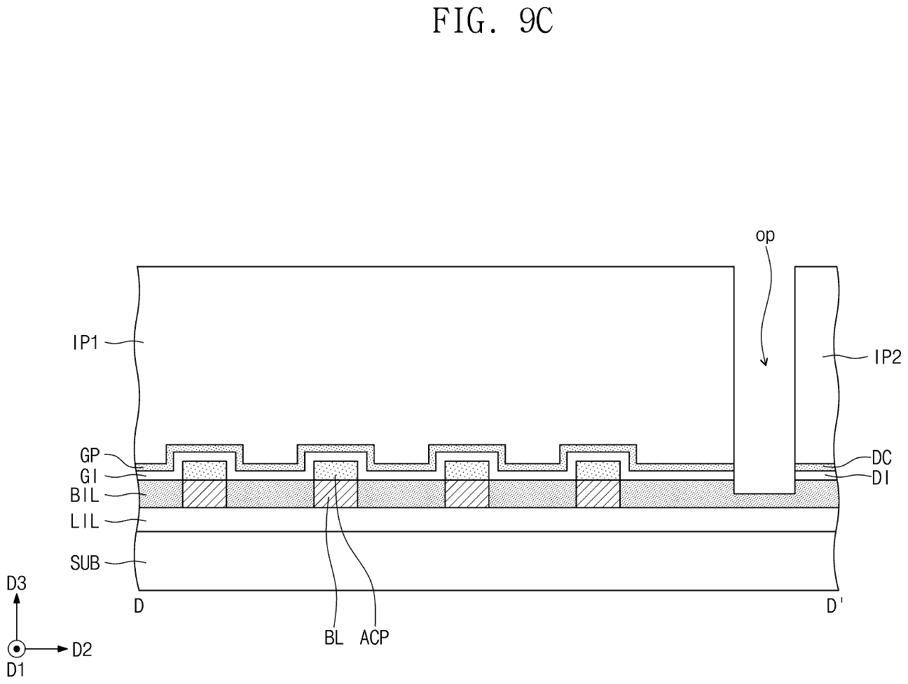

Referring to FIGS. 9A, 9B, and 9C, an opening op may be formed. The formation of the opening op may include forming a photoresist pattern on the preliminary dielectric pattern pIP and the preliminary gate capping layer pGP, performing a photoresist process to form a hole in the photoresist pattern, and using the photoresist pattern as an etch mask to remove a portion of each of the preliminary dielectric pattern pIP, the preliminary gate capping layer pGP, a preliminary gate dielectric layer pGI, the first word lines WL1, the second word lines WL2, and the bit-line dielectric layer BIL.

A portion of the preliminary dielectric pattern pIP may be removed to form a first dielectric pattern IP1 and a second dielectric pattern IP2. The preliminary dielectric pattern pIP whose portion is removed may be defined as the first dielectric pattern IP1 and the second dielectric pattern IP2. A portion of the preliminary gate capping layer pGP may be removed to form a gate capping layer GP and a dummy capping layer DC. The preliminary gate capping layer pGP whose portion is removed may be defined as the gate capping layer GP and the dummy capping layer DC. A portion of the preliminary gate dielectric layer pGI may be removed to form a gate dielectric layer GI and a dummy dielectric layer DI. The preliminary gate dielectric layer pGI whose portion is removed may be defined as the gate dielectric layer GI and the dummy dielectric layer DI.

The opening op may be defined to indicate an empty space formed by removing, through the hole of the photoresist pattern, a portion of each of the preliminary dielectric pattern pIP, the preliminary gate capping layer pGP, a preliminary gate dielectric layer pGI, the first word lines WL1, the second word lines WL2, and the bit-line dielectric layer BIL. In some embodiments, a dry etching process may be employed to remove a portion of each of the preliminary dielectric pattern pIP, the preliminary gate capping layer pGP, a preliminary gate dielectric layer pGI, the first word lines WL1, the second word lines WL2, and the bit-line dielectric layer BIL.

After the formation of the opening op, the photoresist pattern may be removed. In some embodiments, the photoresist pattern may be removed through an ashing process or a strip process.

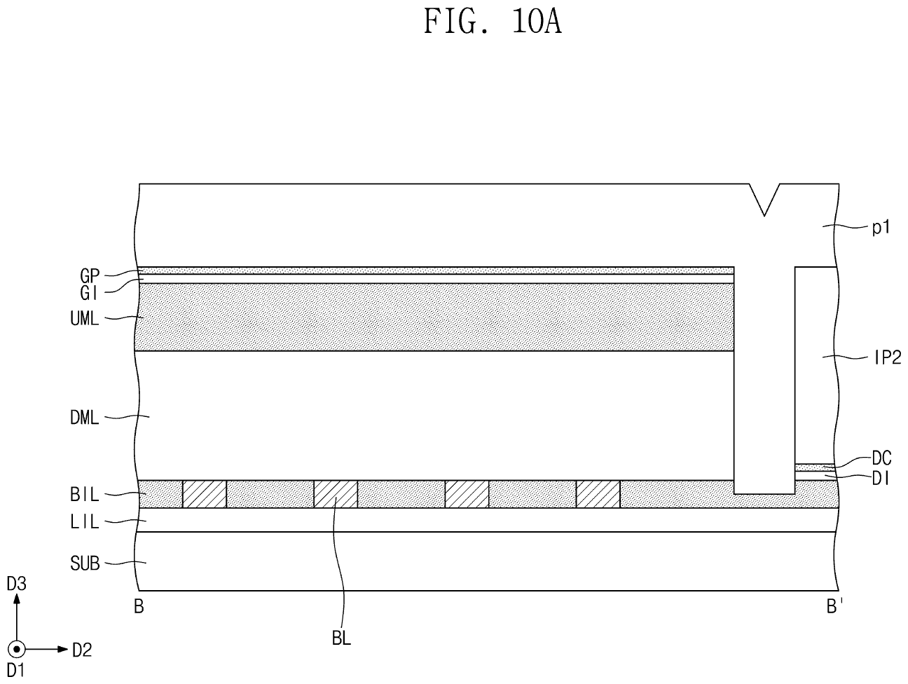

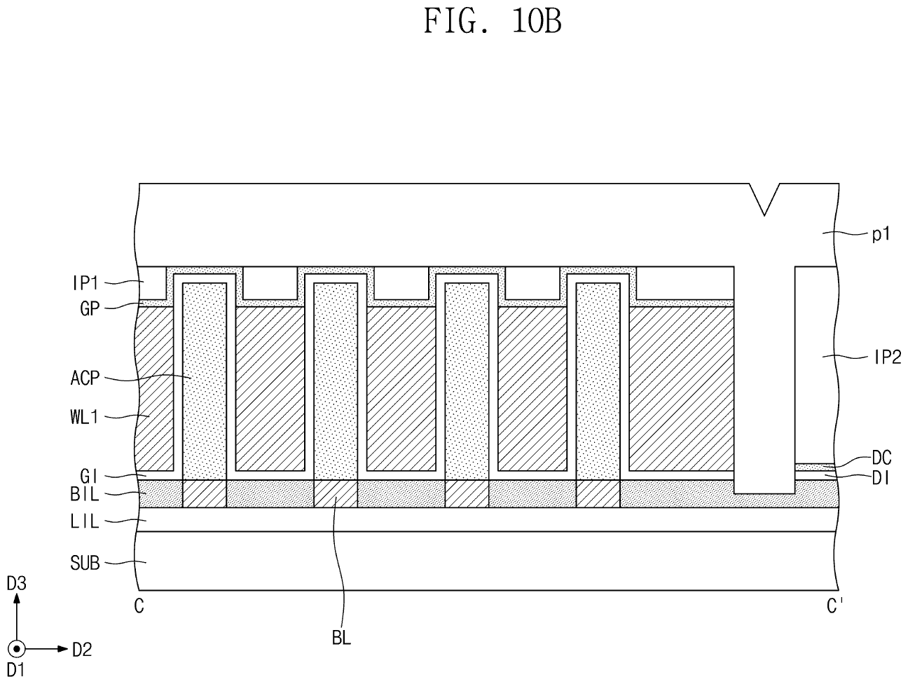

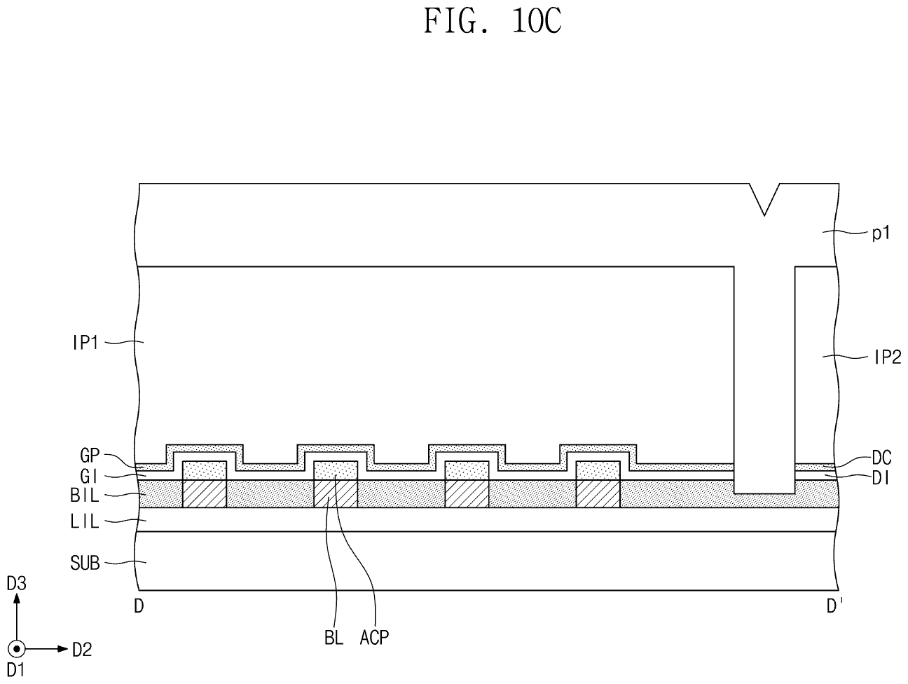

Referring to FIGS. 10A, 10B, and 10C, a preliminary dielectric layer p1 may be formed. The preliminary dielectric layer p1 may be in and may fill the opening op. The preliminary dielectric layer p1 may cover a top surface of each of the gate capping layer GP, the first dielectric pattern IP1, and the second dielectric pattern IP2. The preliminary dielectric layer p1 may include a dielectric material. For example, the preliminary dielectric layer p1 may include oxide. After the formation of the preliminary dielectric layer p1, a heat treatment process may be performed. In some embodiments, the heat treatment process may be performed through an annealing process.

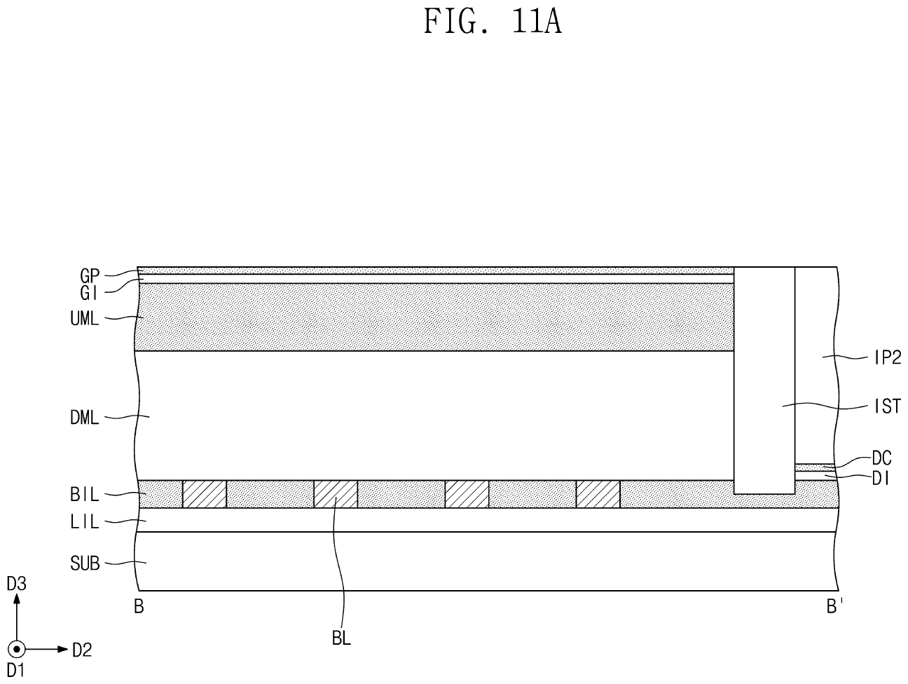

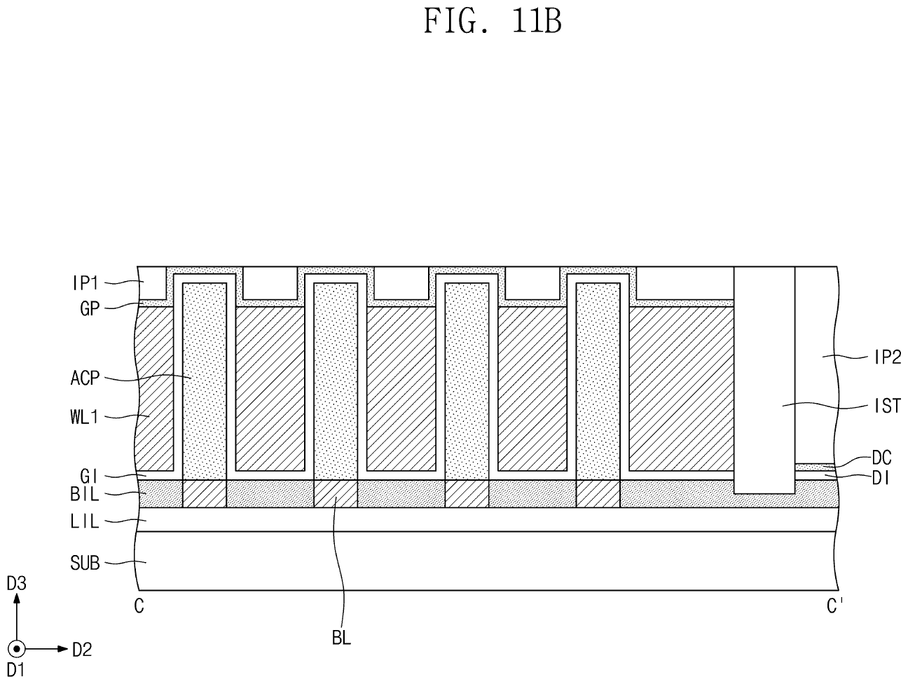

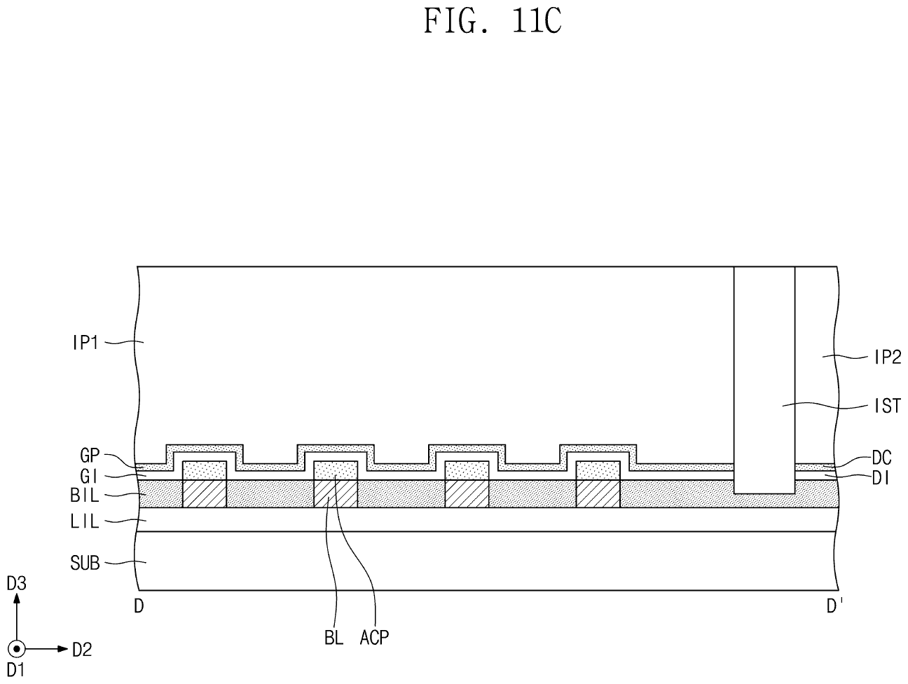

Referring to FIGS. 11A, 11B, and 11C, an upper portion of the preliminary dielectric layer p1 may be removed to form a dielectric structure IST. The preliminary dielectric layer p1 whose upper portion is removed may be defined as the dielectric structure IST. The upper portion of the preliminary dielectric layer p1 may be removed to expose the top surface of each of the gate capping layer GP, the first dielectric pattern IP1, and the second dielectric pattern IP2.

In some embodiments, the upper portion of the preliminary dielectric layer p1 may be removed by a chemical mechanical polishing process or an etch-back process. Thus, the gate capping layer GP, the first dielectric pattern IP1, the second dielectric pattern IP2, and the dielectric structure IST may have their top surfaces that are coplanar with each other.

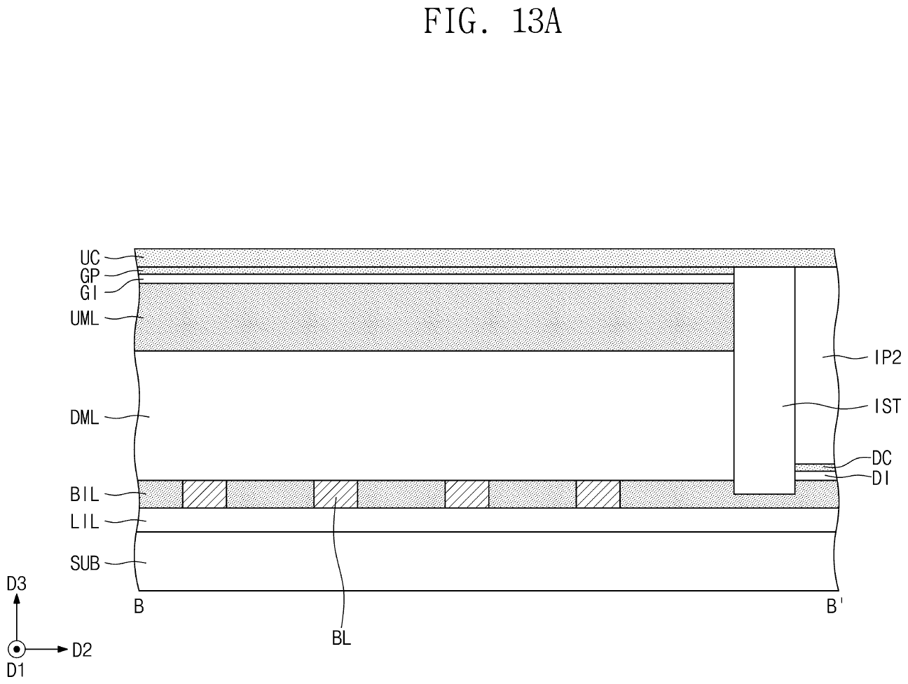

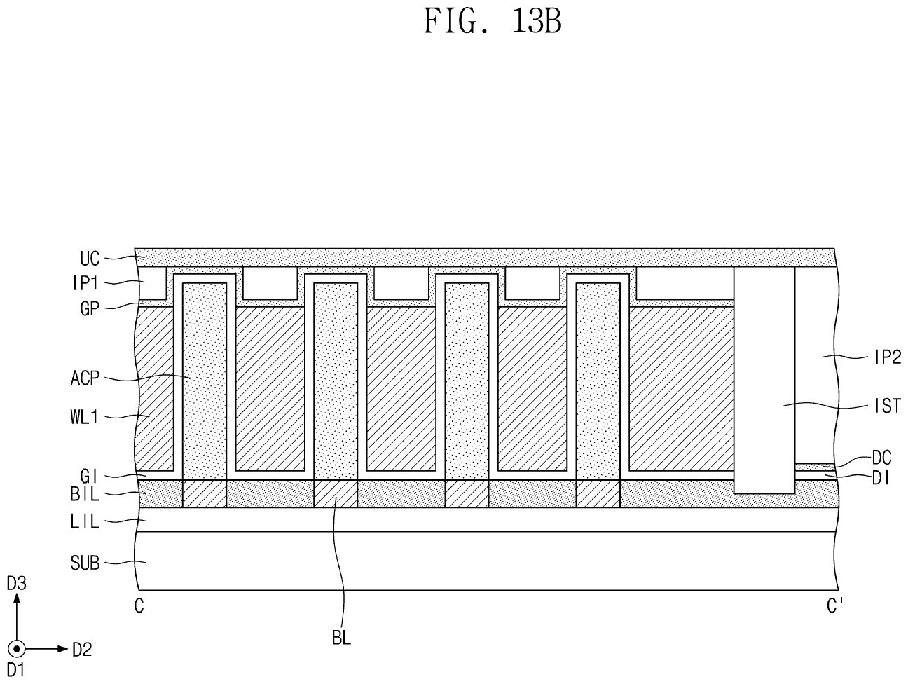

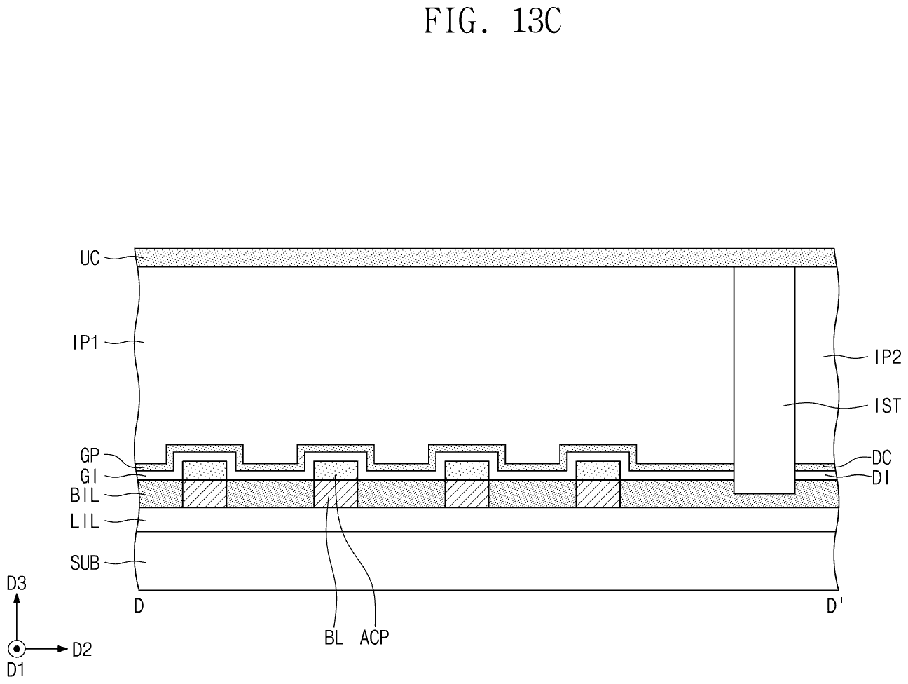

Referring to FIGS. 12, 13A, 13B, and 13C, an upper capping layer UC may be formed. The upper capping layer UC may cover and conform to the exposed top surface of each of the gate capping layer GP, the first dielectric pattern IP1, and the second dielectric pattern IP2.

Referring back to FIGS. 3, 4A, 4B, and 4C, an upper dielectric layer UIL may be formed on the upper capping layer UC. A process may be performed to remove a portion of the upper capping layer UC and a portion of the upper dielectric layer UIL. A landing pad LP may be formed. The landing pad LP may fill an empty space formed by removing the portion of the upper capping layer UC and the portion of the upper dielectric layer UIL. In some embodiments, a portion of each of the channel layer ACP, the gate dielectric layer GI, the gate capping layer GP, the first dielectric pattern IP1, and the upper molding layer UML may be removed together with the portion of the upper capping layer UC and the portion of the upper dielectric layer UIL. The landing pad LP may fill an empty space formed by removing the portion of each of the channel layer ACP, the gate dielectric layer GI, the gate capping layer GP, the first dielectric pattern IP1, and the upper molding layer UML. Data storage patterns DSP may be formed to connect with corresponding ones of the landing pads LP.

In a method of fabricating a semiconductor device according to some embodiments, as the preliminary dielectric layer p1 including oxide is included, an annealing process may be performed to cause oxygen molecules in the preliminary dielectric layer p1 to move through the lower molding layer DML into the channel layer ACP. Therefore, vacancies in the channel layer ACP may be filled with the oxygen molecules to reduce a resistance of the channel layer ACP and to improve electrical properties of the semiconductor device.

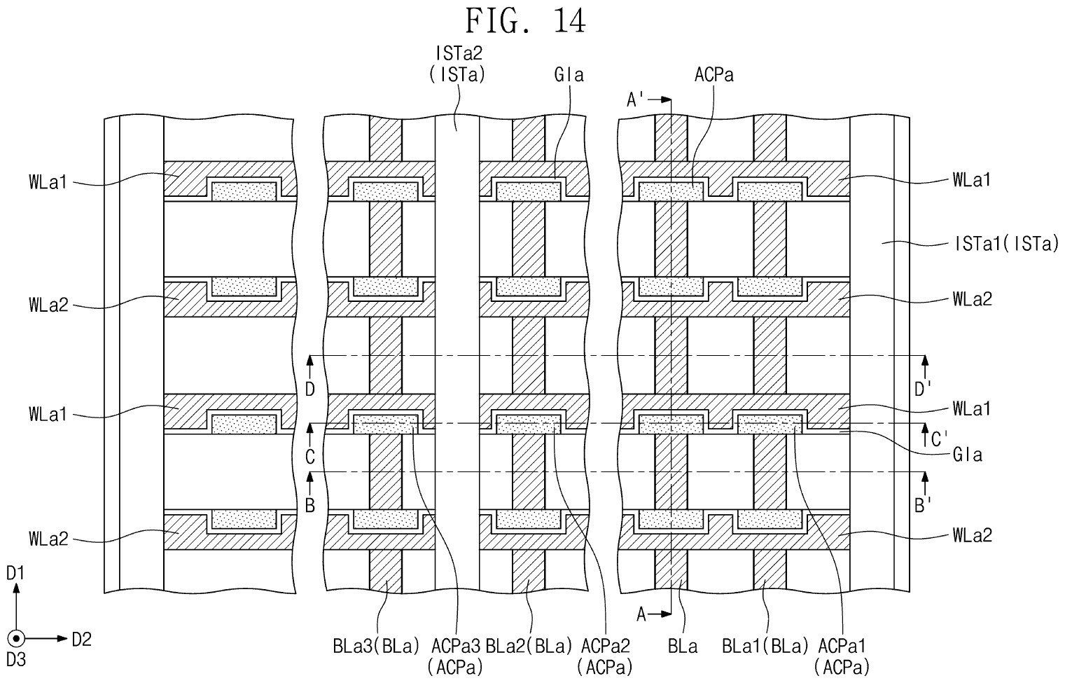

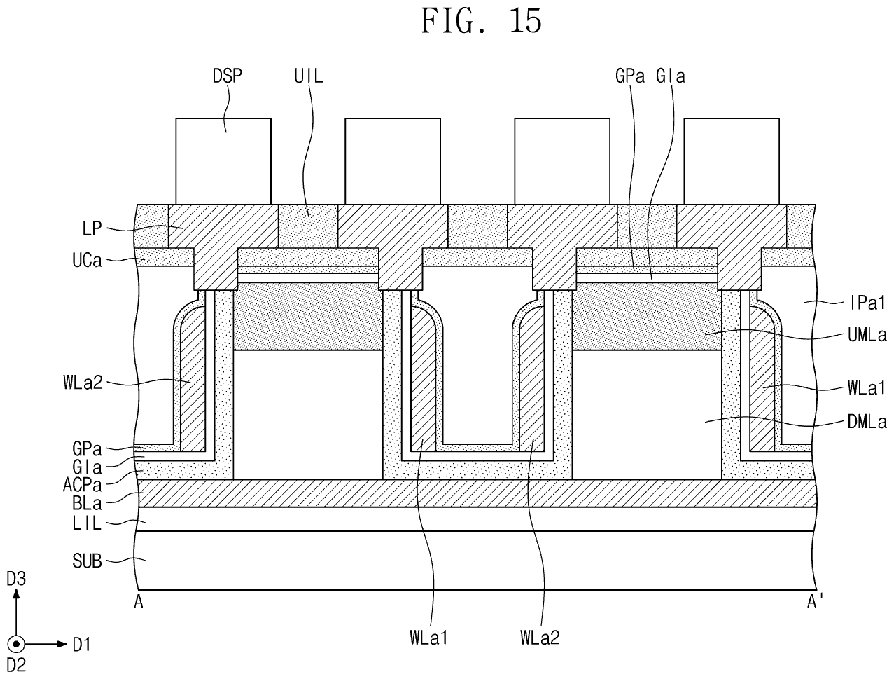

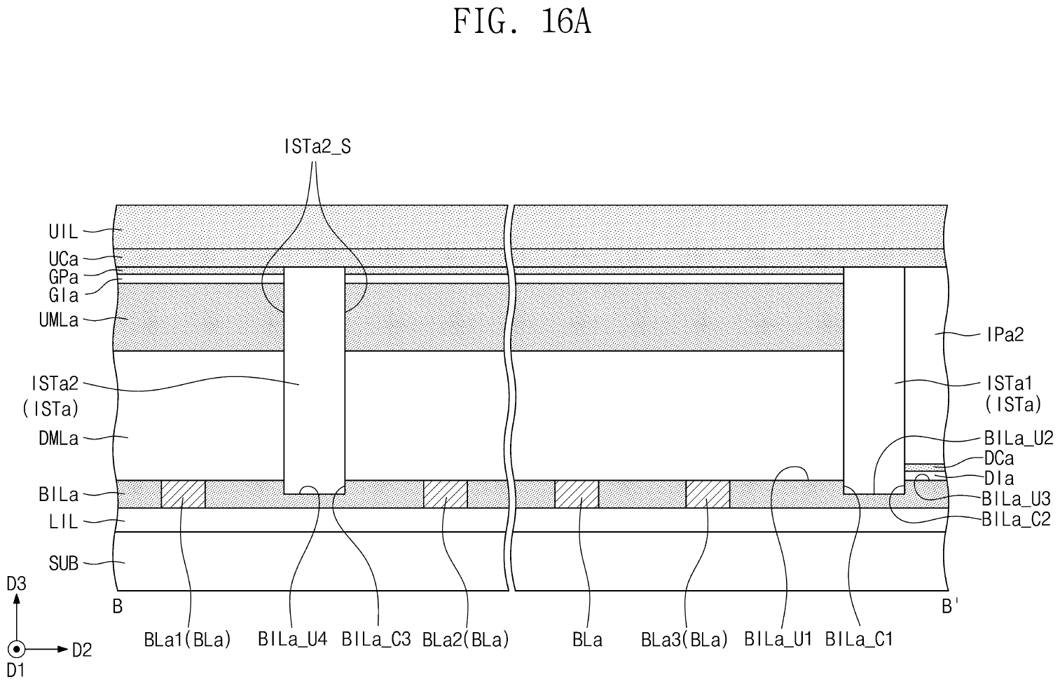

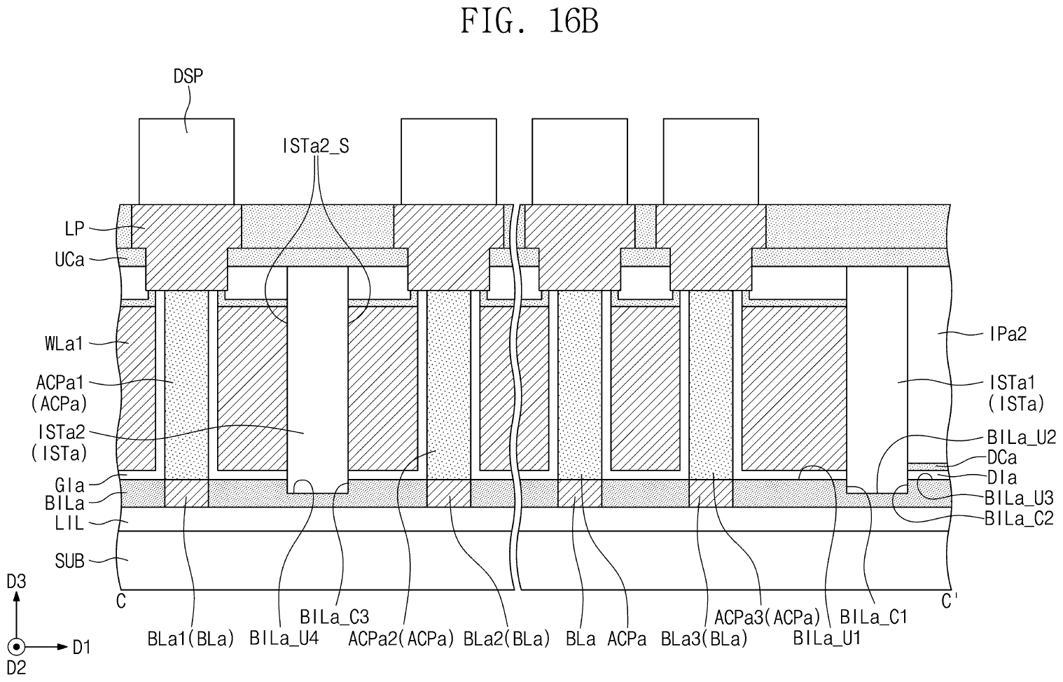

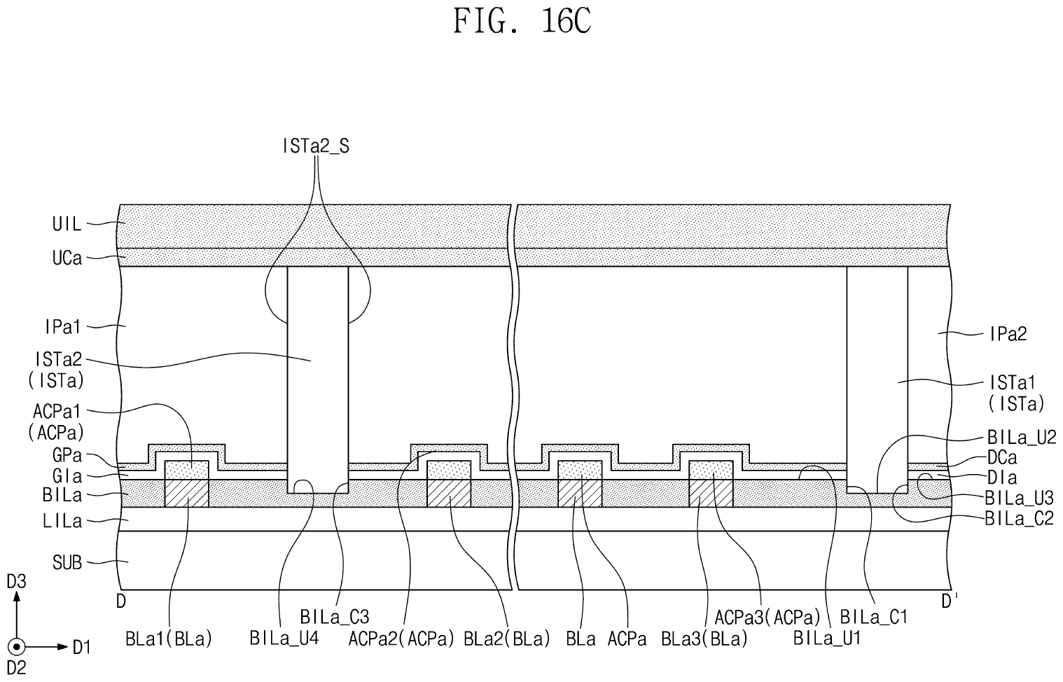

FIG. 14 illustrates a plan view showing a semiconductor device according to some embodiments. FIG. 15 illustrates a cross-sectional view taken along line A-A′ of FIG. 14. FIG. 16A illustrates a cross-sectional view taken along line B-B′ of FIG. 14. FIG. 16B illustrates a cross-sectional view taken along line C-C′ of FIG. 14. FIG. 16C illustrates a cross-sectional view taken along line D-D′ of FIG. 14. A semiconductor device of FIGS. 14 to 16C may be similar to that of FIGS. 2 to 4C, except for the following description.

Referring to FIGS. 14, 15, 16A, 16B, and 16C, a dielectric structure ISTa may include a first dielectric structure ISTa1 and a second dielectric structure ISTa2. The first dielectric structure ISTa1 and the second dielectric structure ISTa2 may be spaced apart from each other in a second direction D2 across the bit lines BL. The first and second dielectric structures ISTa1 and ISTa2 may include a dielectric material. For example, the first and second dielectric structures ISTa1 and ISTa2 may include oxide.

Bit lines BLa may include a first bit line BLa1, a second bit line BLa2, and a third bit line BLa3 that are spaced apart from each other in the second direction D2. The second dielectric structure ISTa2 may be between the first bit line BLa1 and the second bit line BLa2. The first and second bit lines BLa1 and BLa2 may be adjacent to the second dielectric structure ISTa2. The third bit line BLa3 may be adjacent to the first dielectric structure ISTa1. The second bit line BLa2 and the third bit line BLa3 may be between the first dielectric structure ISTa1 and the second dielectric structure ISTa2.

Channel layers ACPa may include a first channel layer ACP1a1, a second channel layer ACPa2, and a third channel layer ACPa3 that are spaced apart from each other in the second direction D2. The first channel layer ACPa1 may be provided on the first bit line BLa1. The second channel layer ACPa2 may be provided on the second bit line BLa2. The third channel layer ACPa3 may be provided on the third bit line BLa3. The second dielectric structure ISTa2 may be between the first channel layer ACPa1 and the second channel layer ACPa2. The first and second channel layers ACPa1 and ACPa2 may be adjacent to the second dielectric structure ISTa2. The third channel layer ACPa3 may be adjacent to the first dielectric structure ISTa1. The second channel layer ACPa2 and the third channel layer ACPa3 may be between the first dielectric structure ISTa1 and the second dielectric structure ISTa2.

The first dielectric structure ISTa1 may be similar to the dielectric structure IST discussed in FIGS. 2 to 4C.

The second dielectric structure ISTa2 may be spaced apart from a dummy dielectric layer DIa, a dummy capping layer DCa, and the second dielectric pattern IPa2. The second dielectric structure ISTa2 may separate first word lines WLa1 from each other in the second direction D2. The second dielectric structure ISTa2 may separate second word lines WLa2 from each other in the second direction D2. The second dielectric structure ISTa2 may separate gate dielectric layers Gla from each other in the second direction D2. The second dielectric structure ISTa2 may separate gate capping layers GPa from each other in the second direction D2. The second dielectric structure ISTa2 may separate first dielectric patterns IPa1 from each other in the second direction D2. The second dielectric structure ISTa2 may separate lower molding layers DMLa from each other in the second direction D2. The second dielectric structure ISTa2 may separate upper molding layers UMLa from each other in the second direction D2.

A bit-line dielectric layer BILa may include a first top surface BILa_U1, a second top surface BILa_U2, a third top surface BILa_U3, a first connection surface BILa_C1, and a second connection surface BILa_C2, and may further include a fourth top surface BILa_U4 and a third connection surface BILa_C3. The fourth top surface BILa_U4 and the third connection surface BILa_C3 of the bit-line dielectric layer BILa may be in contact with the second dielectric structure ISTa2. The fourth top surface BIL_U4 of the bit-line dielectric layer BILa may be located at a level lower than that of the first top surface BILa_U1 of the bit-line dielectric layer BILa and that of the third top surface BILa_U3 of the bit-line dielectric layer BILa. The third connection surface BILa_C3 of the bit-line dielectric layer BILa may connect to each other the first top surface BILa_U1 and the fourth top surface BILa_U4 of the bit-line dielectric layer BILa.

The second dielectric structure ISTa2 may have sidewalls ISTa2_S, a bottom surface, and a top surface. Each of the sidewalls ISTa2_S of the second dielectric structure ISTa2 may be in contact with the third connection surface BILa_C3 of the bit-line dielectric layer BILa, the first word line WL1a, the second word line WLa2, the gate dielectric layer GIa, the gate capping layer GPa, the first dielectric pattern IPa1, the lower molding layer DMLa, and the upper molding layer UMLa. The bottom surface of the second dielectric structure ISTa2 may be in contact with the fourth top surface BILa_U4 of the bit-line dielectric layer BILa. The top surface of the second dielectric structure ISTa2 may be in contact with an upper capping layer UCa.

A semiconductor device according to some embodiments of the present inventive concepts may include a dielectric structure that supplies a channel layer with oxygen molecules when an annealing process is performed. Thus, vacancies of the channel layer may be filled with the oxygen molecules to reduce a resistance of the channel layer and to improve electrical properties of the semiconductor device.

In a method of fabricating a semiconductor device according to some embodiments of the present inventive concepts, oxygen molecules in a preliminary dielectric layer may move through a lower molding layer into a channel layer, and thus vacancies in the channel layer may be filled with the oxygen molecules to reduce a resistance of the channel layer and to improve electrical properties of the semiconductor device.

Although the present inventive concepts have been described in connection with some examples of embodiments of the present inventive concepts illustrated in the accompanying drawings, it will be understood to those skilled in the art that various changes and modifications may be made without departing from the technical spirit and essential feature of the present inventive concepts. It will be apparent to those skilled in the art that various substitution, modifications, and changes may be thereto without departing from the scope of the present inventive concepts.

What is claimed is:

1. A semiconductor device, comprising:
a bit line that extends in a first direction;
a bit-line dielectric layer on a sidewall of the bit line;
a channel layer in contact with the bit line;
a word line that extends in a second direction that intersects the first direction;
a gate capping layer in contact with a first sidewall of the word line;
a gate dielectric layer in contact with the channel layer and a second sidewall of the word line, the second sidewall of the word line opposite to the first sidewall; and
a first dielectric structure that extends in the first direction,
wherein the first dielectric structure includes a dielectric material that is different from a dielectric material of the gate capping layer, and
wherein the word line, the gate dielectric layer, and the gate capping layer are in contact with an inner sidewall of the first dielectric structure.

2. The semiconductor device of claim 1, further comprising:
a first dielectric pattern in contact with the gate capping layer;
a second dielectric pattern spaced apart from the first dielectric pattern across the first dielectric structure; and
a dummy dielectric layer and a dummy capping layer between the bit-line dielectric layer and the second dielectric pattern,
wherein the first dielectric structure includes an outer sidewall in contact with the dummy dielectric layer, the dummy capping layer, and the second dielectric pattern.

3. The semiconductor device of claim 2, further comprising an upper capping layer in contact with a top surface of the first dielectric pattern,
wherein the gate capping layer has a top surface in contact with the upper capping layer, and
wherein the top surface of the gate capping layer, the top surface of the first dielectric pattern, and a top surface of the first dielectric structure are coplanar with each other.

4. The semiconductor device of claim 1, further comprising a lower molding layer in contact with the bit line and the channel layer,
wherein the lower molding layer is in contact with the inner sidewall of the first dielectric structure.

5. The semiconductor device of claim 4, wherein the lower molding layer and the first dielectric structure include an oxide.

6. The semiconductor device of claim 4, wherein a bottom surface of the lower molding layer and a bottom surface of the first dielectric structure are coplanar with each other.

7. The semiconductor device of claim 1, further comprising a second dielectric structure spaced apart in the second direction from the first dielectric structure across the channel layer,
wherein the second dielectric structure includes a dielectric material that is the same as a dielectric material of the first dielectric structure and is in contact with the bit-line dielectric layer.

8. The semiconductor device of claim 7, wherein the bit line includes a first bit line, a second bit line, and a third bit line that are spaced apart from each other in the second direction,
wherein the second and third bit lines are between the first dielectric structure and the second dielectric structure, and
wherein the second dielectric structure is between the first bit line and the second bit line.

9. The semiconductor device of claim 8, wherein the channel layer includes:
a first channel layer on the first bit line;
a second channel layer on the second bit line; and
a third channel layer on the third bit line,
wherein the second dielectric structure is between the first channel layer and the second channel layer.

10. The semiconductor device of claim 1, further comprising an upper capping layer that is in contact with a top surface of the first dielectric structure and a top surface of the gate capping layer.

11. The semiconductor device of claim 1, further comprising a lower dielectric layer on a bottom surface of the bit line,
wherein a bottom surface of the first dielectric structure is in contact with the lower dielectric layer.

12. The semiconductor device of claim 11, wherein a level of the bottom surface of the first dielectric structure is lower than a level of the bottom surface of the bit line.

13. The semiconductor device of claim 1, wherein the dielectric material of the first dielectric structure is different from a dielectric material of the bit-line dielectric layer.

14. A semiconductor device, comprising:
a bit line that extends in a first direction;
a bit-line dielectric layer on a sidewall of the bit line;
a channel layer in contact with the bit line;
a word line that extends in a second direction that intersects the first direction;
a gate capping layer in contact with a first sidewall of the word line;
a gate dielectric layer in contact with the channel layer and a second sidewall of the word line, the second sidewall of the word line being opposite to the first sidewall; and
a dielectric structure in contact with a third sidewall of the word line,
wherein the gate dielectric layer and the dielectric structure each include an oxide, and
wherein the bit-line dielectric layer includes:
a first top surface in contact with the gate dielectric layer; and
a second top surface in contact with a bottom surface of the dielectric structure.

15. The semiconductor device of claim 14, wherein the bit-line dielectric layer further has a connection surface that connects the first top surface to the second top surface, and
wherein the connection surface of the bit-line dielectric layer is in contact with an inner sidewall of the dielectric structure.

16. The semiconductor device of claim 14, wherein the channel layer includes a first channel layer and a second channel layer that are spaced apart from each other in the second direction,
wherein the dielectric structure is between the first channel layer and the second channel layer.

17. The semiconductor device of claim 14, further comprising a lower molding layer that is in contact with the bit line and the channel layer,
wherein the lower molding layer connects the channel layer to the dielectric structure.

18. The semiconductor device of claim 17, further comprising an upper molding layer between the lower molding layer and the gate dielectric layer,
wherein the upper molding layer includes a dielectric material that is different from a dielectric material of the dielectric structure and is in contact with an inner sidewall of the dielectric structure.

19. A semiconductor device, comprising:
a bit line that extends in a first direction;
a bit-line dielectric layer on a sidewall of the bit line;
a channel layer in contact with the bit line;
a word line that extends in a second direction that intersects the first direction;
a gate capping layer in contact with a first sidewall of the word line;
a gate dielectric layer in contact with the channel layer and a second sidewall of the word line, the second sidewall of the word line being opposite to the first sidewall;
a dielectric structure in contact with a third sidewall of the word line;
a first dielectric pattern in contact with the gate capping layer;
a second dielectric pattern spaced apart from the first dielectric pattern across the dielectric structure;
an upper capping layer in contact with the gate capping layer, the first dielectric pattern, and the second dielectric pattern;
an upper dielectric layer on the upper capping layer;
a landing pad that extends at least into the upper dielectric layer and is in contact with the channel layer; and
a data storage pattern connected to the landing pad,
wherein a bottom surface of the upper capping layer is in contact with a top surface of the dielectric structure.

20. The semiconductor device of claim 19, wherein the word line includes a first word line and a second word line that are spaced apart from each other in the first direction,
wherein the first word line and the second word line are in contact with an inner sidewall of the dielectric structure.
